(19) United States
(12) Patent Application Publication
(10) Pub. No.: US 2009/0238021 A1
(43) Pub. Date: Sep. 24, 2009

(54) Semiconductor memory device and operation method therefor

(75) Inventors: Koji Ban, Shizuoka (JP); Kotaro Kashiwa, Kanagawa (JP)

Correspondence Address: LERNER, DAVID, LITTENBERG,;KRUMHOLZ & MENTLIK, 600 SOUTH AVENUE WEST, WESTFIELD, NJ, 07090, US

(73) Assignee: Sony Corporation, Tokyo (JP)

(21) Appl. No.: 12/321,906

(22) Filed: Jan. 27, 2009

(30) Foreign Application Priority Data
Jan. 31, 2008 (JP) P2008-021710

(51) Int. Cl. G11C 7/00; G11C 8/00

(52) U.S. Cl. 365/222; 365/230.03

(57) ABSTRACT

Disclosed herein is a semiconductor memory device, including: a memory array section wherein a memory array which requires a refresh operation is formed; an interface section configured to carry out an interfacing process between an external apparatus and the memory array section; and a refresh control block for controlling the refresh operation; the interface section configured to include a plurality of interface modules individually corresponding to a plurality of memory types and selectively applied to the interfacing process between the external apparatus and the memory array section; the refresh control block having a function of issuing a refresh command within a refresh cycle and another function of preventing, if, upon issuance of the refresh command, an access command and the refresh command to the memory array are estimated to collide with each other, the collision.

### CROSS REFERENCES TO RELATED APPLICATIONS

The present invention contains subject matter related to Japanese Patent Application JP 2008-021710 filed in the Japan Patent Office on Jan. 31, 2008, the entire contents of which being incorporated herein by reference.

### BACKGROUND OF THE INVENTION

1. Field of the Invention

This invention relates to a semiconductor memory device and an operation method therefor.

2. Description of the Related Art

Various memory types which are different in circuit configuration, operation function and so forth are known for a semiconductor memory device which is used as a RAM (random access memory) chip in various electronic apparatus.

Semiconductor memory devices can be roughly classified into DRAM (Dynamic Random Access Memory) devices and SRAM (Static Random Access Memory) devices from the circuit configuration and the operation.

An SDRAM (Synchronous Dynamic Random Access Memory) is known as a kind of DRAM and outputs data in synchronism with a clock supplied thereto from the outside. As such SDRAM devices, an SDR-SDRAM (Single Data Rate SDRAM) device, a DDR-SDRAM (Double Data Rate SDRAM) device, a DDR2-SDRAM device, DDR3-SDRAM, . . . , DDR(n)-SDRAM devices and so forth are known.

Meanwhile, from a point of view of the structure, also a DPRAM (Dual Port RAM) device having a plurality of access ports is available, and from a point of view of the function, also a FIFO (First in First out) type RAM device which does not require address designation is available.

Such various memory types are selectively used properly in accordance with requirements in each electronic apparatus.

It is to be noted that, in the following description, a DR-SDRAM device is referred to as “SDR,” a DDR-SDRAM device as “DDR,” a DDR2-SDRAM device as “DDR2,” DDR3-SDRAM, . . . , DDR(n)-SDRAM devices are referred to as “DDR3,” . . . , “DDR(n),” respectively, and a FIFO type device is referred to as “FIFO.”

Related techniques are disclosed in Japanese Patent Laid-Open No. 2006-65533 and Japanese Patent Laid-Open No. 2004-318500.

### SUMMARY OF THE INVENTION

In various electronic apparatus, the memory type of a semiconductor memory device, that is, a semiconductor memory IC chip, to be incorporated is determined taking required functions and performances, the cost and so forth into consideration.

Then, where a semiconductor memory device of a certain memory type is to be incorporated, a memory controller or memory controlling apparatus for writing/reading information into/from the memory chip is naturally designed or selected so that it carries out memory accessing operation suitable for the memory type.

However, such following problems are frequently encountered from various circumstances.

In particular, all of various semiconductor devices may not always be supplied stably. Particularly in recent years, diversification of semiconductor memory devices has proceeded rapidly in response to technical innovations, requirements of the market and so forth, and besides, development of new type memory devices is carried out positively. On the contrary, it frequently occurs that fabrication of semiconductor memory devices of a type for which the demand decreases is stopped by a memory maker.

To an apparatus maker which incorporates a certain type of semiconductor memory devices into an electronic apparatus for commercialization, stoppage of fabrication of semiconductor memory devices of the adopted memory type becomes a serious problem.

For example, it is assumed that an apparatus maker adopts an SDR to fabricate a certain apparatus.

If it is assumed that supply of the SDR becomes unstable, then the apparatus maker need consider incorporating another semiconductor memory device into the apparatus in place of the SDR.

Therefore, the apparatus maker may incorporate the DDR in place of the SDR. In this instance, it becomes necessary for the apparatus maker not only to change the chip of the semiconductor memory device from the SDR to the DDR but also to carry out specification change of a memory controller for accessing to the semiconductor memory device.

As occasion demands, a significant burden may be imposed in terms of the efficiency, cost and so forth in fabrication because the memory controller or a peripheral circuit must be re-designed or from a like reason.

On the other hand, also when a new electronic apparatus is to be designed, it is necessary to foresee a future situation of supply of semiconductor memory devices.

However, such requirement may disturb the degree of freedom in appropriate and efficient design because it is obliged to adopt a semiconductor memory device having an unnecessarily high processing capacity or circuit design must be carried out taking future specification change of the memory controller and so forth into consideration.

Further, semiconductor memory devices of a certain memory type require a refresh operation like a DRAM. In this instance, the refresh operation is carried out within a cycle set in advance in accordance with a refresh command received from an external apparatus.

Accordingly, even when a refresh operation is not required as yet, if a refresh command is received when a read command or a write command is received, then it is necessary to carry out reading or writing after a refresh operation is carried out. Therefore, there is a disadvantage that a refresh operation suitable for an access situation cannot be carried out and an efficient memory access cannot be carried out.

Therefore, it is demanded to provide a semiconductor memory device which can be used as memories of various memory types.

Also it is demanded to provide an operation method for a semiconductor memory device by which a refresh operation can be carried out in response to an access situation and an efficient memory access can be achieved.

According to an embodiment of the present invention, there is provided a semiconductor memory device including a memory array section wherein a memory array which requires a refresh operation is formed, an interface section configured to carry out an interfacing process between an external apparatus and the memory array section, and a refresh control block configured to control the refresh operation, the interface section including a plurality of interface modules individually corresponding to a plurality of memory types and selectively applied to the interfacing process between the external apparatus and the memory array section, the refresh control block having a function of issuing a refresh command within a refresh cycle and another function of preventing, if, upon issuance of the refresh command, an access command and the refresh command to the memory array are estimated to collide with each other, the collision.

Preferably, the refresh control block further has a function of skipping the refresh command to an address of the memory array which has been accessed within the refresh cycle thereby eliminate the necessity for the refreshment.

More preferably, the refresh control block monitors accessed addresses and skips the refresh command when the refresh control block tries to doubly access any of the accessed addresses within the refresh cycle.

Further preferably, the refresh control block includes a memory for storing address information, and stores information of any address accessed within the refresh cycle into the memory, reads out the information stored in the memory at a timing of accessing to a refresh address and skips the refresh command if the read out information represents an address accessed once within the refresh cycle.

Or, the semiconductor memory device may be configured such that the memory array includes a plurality of banks which can be accessed independently of each other, and the refresh control block does not interrupt the refresh operation if that one of the banks which is currently being accessed and that one of the banks which should be refreshed are different from each other.

Or else, the semiconductor memory device may be configured such that the memory array includes a plurality of banks which can be accessed independently of each other, and the refresh control block interrupts the refresh operation if that one of the banks which is currently being accessed and that one of the banks which should be refreshed are same as each other.

Otherwise, the semiconductor memory device may be configured such that the memory array includes a plurality of banks which can be accessed independently of each other, and if the refresh control block executes an access process to one of the banks before the bank is refreshed, then the refresh control block skips the accessed address.

According to another embodiment of the present invention, there is provided an operation method for a semiconductor memory device having an interface function in accordance with a memory type between a memory array section wherein a memory array which requires a refresh operation is formed and an external apparatus, including the steps of issuing a refresh command within a refresh cycle, and skipping, if an access command and the refresh command to the memory array collide with each other, the refresh command for any address of the memory array accessed within the refresh cycle to eliminate the necessity for the refreshment for the address.

In the semiconductor memory device and the operation method therefor, the refresh control block issues a refresh command within a refresh cycle. If the issued refresh command and an access command to the memory array are estimated to collide with each other, then the refresh command is skipped for an address of the memory array accessed within the refresh period. Consequently, the collision is prevented.

With the semiconductor memory device and the operation method therefor, the semiconductor memory device can be used as memories of various memory types, and besides can carry out a refresh operation in response to an access situation. Consequently, efficient memory accessing can be achieved.

Further, the semiconductor memory device can be used to achieve improvement in efficiency in apparatus fabrication and design and stabilization in fabrication.

For example, if supply of a memory of a certain memory type for use in an electronic apparatus which incorporates a memory of the memory type becomes unstable, then if the memory is replaced by the semiconductor memory device and the semiconductor memory device is set so that it executes operation similar to that of the memory formerly used, then fabrication of the apparatus can be continued without changing the design of a memory control circuit or peripheral circuits.

Further, where a new electronic apparatus is to be designed, if the semiconductor memory device is adopted as a memory chip to be incorporated in the electronic apparatus, then the electronic apparatus can be designed efficiently with a high degree of freedom. Also in a case wherein it is intended to carry out a specification change of the memory itself in the future, the semiconductor memory device can cope with the case readily.

The above and other features and advantages of the present invention will become apparent from the following description and the appended claims, taken in conjunction with the accompanying drawings in which like parts or elements denoted by like reference symbols.

### BRIEF DESCRIPTION OF THE DRAWINGS

FIGS. 1A to 1C are schematic views showing a basic general configuration of a semiconductor memory device to which an embodiment of the present invention is applied;

FIG. 2 is a block diagram showing a particular circuit configuration of the semiconductor memory device;

FIG. 3 is a block diagram showing an example of a configuration of a DRAM-IF module group shown in FIG. 2;

FIGS. 4 and 5 are diagrammatic views illustrating state transitions of an SDRAM and a DDR-SDRAM, respectively;

FIG. 6 is a block diagram showing an example of a configuration of modified semiconductor memory device which includes an IF module without using a common sequence unit and a special-purpose module unit separate from each other;

FIG. 7 is a diagrammatic view illustrating state transitions of a DRAM-IF module group which includes a common sequence unit and a special-purpose module unit;

FIG. 8 is a block diagram illustrating an operation state of the semiconductor memory device of FIG. 2;

FIGS. 9A to 9C are waveform diagrams illustrating state transitions upon initializing;

FIGS. 10A to 10C are waveform diagrams illustrating state transitions upon writing;

FIGS. 11A to 11C are waveform diagrams illustrating state transitions upon writing with automatic precharge;

FIGS. 12A to 12C are waveform diagrams illustrating state transitions upon reading out;

FIGS. 13A to 13C are waveform diagrams illustrating state transitions upon reading out with automatic precharge;

FIGS. 14A and 14B are waveform diagrams illustrating state transitions upon automatic refresh;

FIG. 15 is a block diagram showing an example of a configuration of a refresh control block shown in FIG. 2 and an adaptive converter;

FIG. 16 is a timing chart illustrating writing operation under the control of the refresh control block;

FIG. 17 is a timing chart illustrating reading out operation under the control of the refresh control block;

FIG. 18 is a timing chart illustrating clearing operation under the control of the refresh control block;

FIG. 19 is a timing chart illustrating a general image of a refresh cycle by the semiconductor memory device shown in FIG. 2;

FIGS. 20 to 22 are timing charts illustrating different examples of refresh operation of the semiconductor memory device shown in FIG. 2;

FIGS. 23A and 23B are timing charts illustrating reading and writing cycle timings of an SDR, respectively;

FIGS. 24A and 24B are timing charts illustrating reading and writing cycle timings of a DDR, respectively;

FIGS. 25A to 25G are waveform diagrams illustrating operation of an SDR-IF module shown in FIG. 2 when it functions;

FIGS. 26A to 26I are waveform diagrams illustrating operation of a DDR-IF module shown in FIG. 2 when it functions;

FIG. 27 is a block diagram illustrating mode operation of a PLL (phase locked loop) block shown in FIG. 2;

FIG. 28 is a block diagram illustrating mode operation of a selector shown in FIG. 2;

FIGS. 29 to 33 are block diagrams illustrating mode operations of an IO buffer shown in FIG. 2;

FIG. 34 is a block diagram showing another example of the configuration the semiconductor memory device of FIG. 2;

FIG. 35 is a block diagram illustrating an operation state of the semiconductor memory device of FIG. 34;

FIG. 36 is a block diagram showing a further example of the configuration of the semiconductor memory device of FIG. 2; and

FIG. 37 is a block diagram illustrating an operation state of the semiconductor memory device of FIG. 36.

### DETAILED DESCRIPTION OF THE PREFERRED EMBODIMENT

A. preferred embodiment of the present invention is described in the following order.

1. Outline of the Semiconductor memory device

2. Internal Configuration and Operation of the Semiconductor Memory Device

3. Mode Operation of the PLL block

4. Mode Operation of the Selector

5. Mode Operation of the IO Buffer

6. Other Examples of the Configuration of the Semiconductor Memory Device

### 1. Outline of the Semiconductor Memory Device

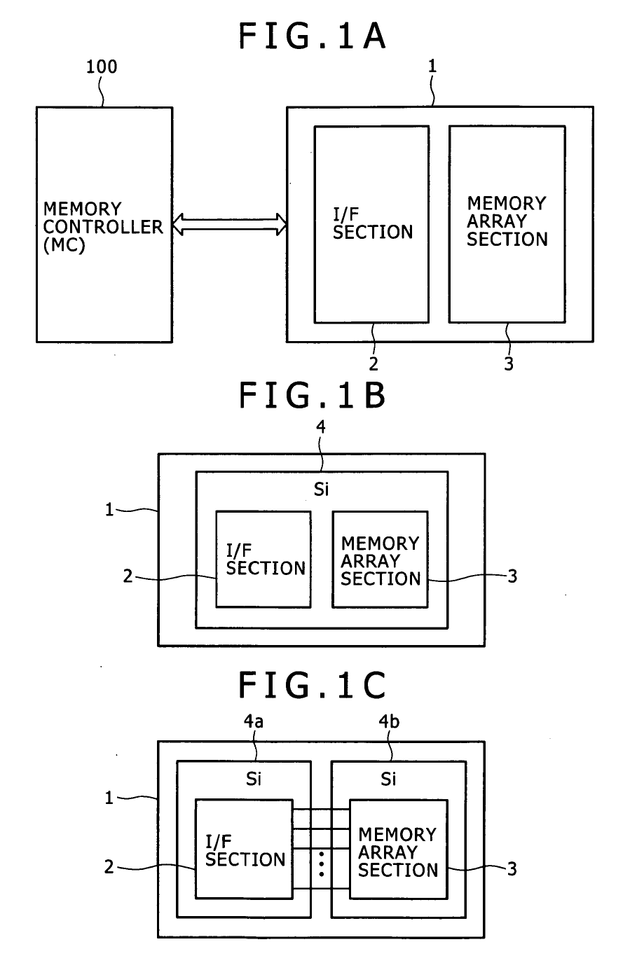

FIGS. 1A to 1C show a basic general configuration of a semiconductor memory device according to an embodiment of the present invention.

FIG. 1A shows a memory controller (MC) 100 as an external apparatus and a semiconductor memory device 1 according to the embodiment of the present invention.

Referring to FIG. 1A, the semiconductor memory device 1 is used as a memory IC in a certain electronic apparatus and accessed for writing/reading, and further, depending upon the memory type, for erasure, by the memory controller 100 incorporated in the electronic apparatus.

The memory controller 100 handles the semiconductor memory device 1 as a memory of a particular memory type in accordance with design specifications thereof.

For example, where the memory controller 100 in the electronic apparatus is designed so as to carry out an accessing process to a DDR, the semiconductor memory device 1 carries out inputting and outputting similar to those for a DDR for the memory controller 100. In particular, after the semiconductor memory device 1 is mounted in circuitry of the electronic apparatus and electrically connected to the memory controller 100, the semiconductor memory device 1 functions as a DDR.

On the other hand, where the memory controller 100 in the electric apparatus is designed so as to carry out an accessing process for an SDR, the semiconductor memory device 1 carries out inputting and outputting similar to those for an SDR for the memory controller 100. In other words, after the semiconductor memory device 1 is mounted in circuitry of the electronic apparatus and electrically connected to the memory controller 100, the semiconductor memory device 1 functions as an SDR.

Therefore, for example, in a case wherein electronic apparatus in which an SDR is mounted have been fabricated, if such a situation that the fabrication of the SDR is stopped by the supplying source of the SDR occurs, then if the semiconductor memory device 1 is mounted in place of the SDR and is caused to operate as an SDR, then the fabrication of the electronic apparatus can be continued without any modification to the memory controller 100 and so forth.

Further, if the semiconductor memory device 1 is adopted in an electronic apparatus to be developed newly, then the degree of freedom in design of the memory controller 100 and peripheral circuits is improved, and even if the necessity for future alteration of the memory type occurs, this can be coped with readily.

The semiconductor memory device 1 is formed as a monolithic memory IC of one package and has an interface section (I/F) 2 and a memory array section or RAM array section 3 formed therein.

The memory array section 3 is formed in a structure as a DRAM or an SRAM.

The interface section 2 includes input/output buffers from/to the memory controller 100, a plurality of interface modules corresponding to different memory types and so forth.

In the semiconductor memory device 1, the interface section 2 having a plurality of interface modules individually corresponding to different memory types and the memory array section 3 formed as an information storage region are integrated and sealed in a package.

FIGS. 1B and 1C show different examples of the internal structure of the package.

In particular, FIG. 1B shows an example wherein the memory array section 3 and the interface section 2 are sealed in a package in a state wherein they are formed on a single silicon die 4.

Meanwhile, FIG. 1C shows another example wherein the memory array section 3 and the interface section 2 are formed on different silicon dies 4a and 4b and are sealed in a package in another state wherein they are connected to each other.

### 2. Internal Configuration and Operation of the Semiconductor Memory Device

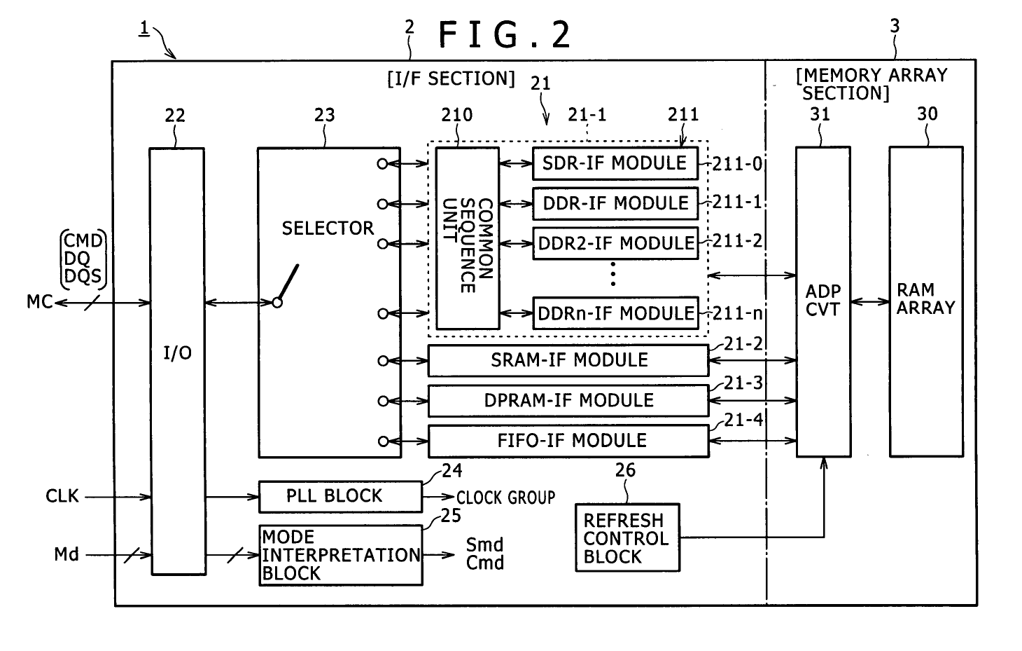

FIG. 2 shows an example of a particular circuit configuration of the semiconductor memory device 1.

Referring to FIG. 2, the semiconductor memory device 1 includes the interface section 2 and the memory array section 3 as described above.

The interface section 2 includes an interface (I/F) module group 21 (21-1, 21-2, . . . , 21-4), an IO buffer 22, a selector 23, a PLL (phase locked loop) block 24, a mode interpretation block 25 and a refresh control block 26.

Meanwhile, the memory array section 3 includes a RAM array 30 and an adaptive converter (ADPCVT) 31.

The RAM array 30 is formed, for example, as an information storage region of a DRAM or an SRAM. The RAM array 30 can be designed freely in terms of the cell structure and so forth in accordance with various requirements. In the present embodiment, the RAM array 30 is formed as a memory array which requires a refresh operation.

The adaptive converter 31 carries out control signal conversion between the RAM array 30 and interface modules of the interface module group.

The adaptive converter 31 is provided so as to carry out signal conversion in response to specifications of the RAM array 30 in order to implement a general interface, for example, as a DRAM or an SRAM.

In the interface section 2, the IO buffer 22 carries out electrical interfacing between the semiconductor memory device 1 and an external apparatus such as, for example, the memory controller 100.

The IO buffer 22 transfers a command CMD, input/output data DQ and a data strobe signal DQS to and from the memory controller 100.

Further, the IO buffer 22 receives a system clock CLK supplied, for example, from the memory controller 100 as an input thereto and supplies the system clock CLK to the PLL block 24.

Further, the IO buffer 22 receives a mode designation signal Md as an input thereto and supplies the mode designation signal Md to the mode interpretation block 25.

The mode designation signal Md is indicative of an operation mode of the semiconductor memory device 1, that is, a memory type of a memory as which the semiconductor memory device 1 is to operate.

The mode designation signal Md may have a logic value set, for example, by a small-sized DIP switch formed on the package of the semiconductor memory device 1.

Or, a predetermined number of pins for mode setting may be formed on the package such that logical values depending upon the connection state of the pins, for example, logical values by H/L (High/Low) impedance values, are used as the mode designation signal Md.

Further, the memory controller 100 may supply the mode designation signal Md to the semiconductor memory device 1.

The selector 23 selects one of the interface modules of the interface module group 21 and connects the selected interface module to the IO buffer 22. The selection of the selector 23 is carried out based on a mode signal Smd from the mode interpretation block 25.

The interface module group 21 includes a plurality of interface modules of different memory types.

For example, in the example shown in FIG. 2, the interface module group 21 includes a DRAM interface (I/F) module group 21-1, an SRAM-IF module 21-2, a DPRAM-IF module 21-3 and a FIFO-IF module 21-4.

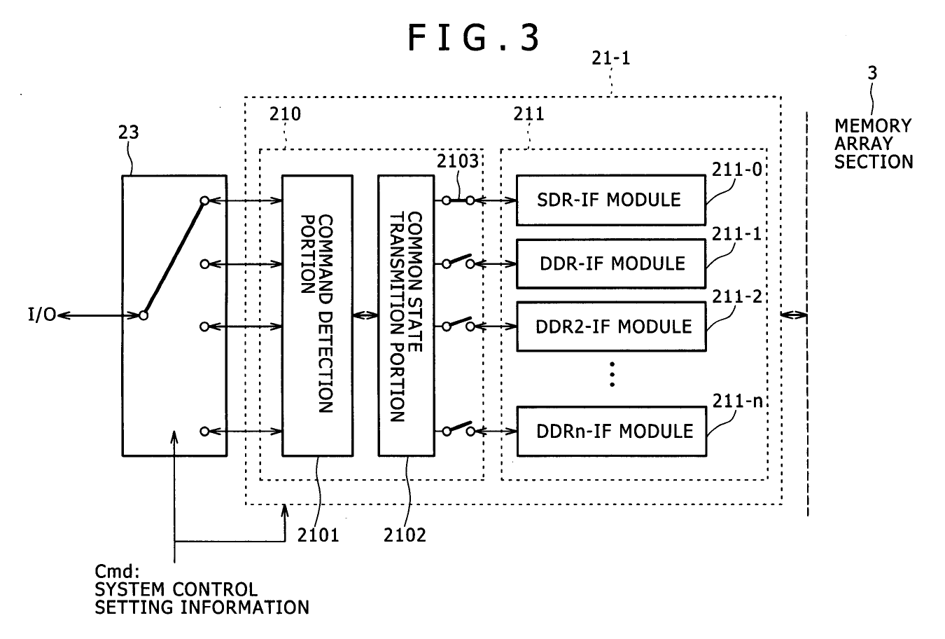

FIG. 3 shows an example of a configuration of the DRAM interface module group 21-1.

Referring to FIG. 3, the DRAM interface module group 21-1 is configured by forming those of state transitions of the different DRAM-IF modules which are common among the DRAM-IF modules as a common sequence and forming those of the state transitions which are different among the DRAM-IF modules as special-purpose modules of exceptional processes.

This implements simplification of a state transition circuit of a multi-interface RAM (multi-IF RAM).

In particular, the DRAM interface module group 21-1 includes a common sequence unit 210 and a special-purpose module unit 211.

The common sequence unit 210 includes a command detection portion 2101 for detecting a command from the memory controller 100 supplied thereto through the IO buffer 22 and the selector 23. The common sequence unit 210 further includes a common state transition portion 2102 for carrying out a common sequence process of the common portion in response to a result of the detection of the command detection portion 2101 and causing the special-purpose module unit 211 to carry out an exceptional process. The common sequence unit 210 further includes a switch group 2103 for separating process portions unique to the individual memory interfaces from the common sequence portion and selectively transferring the unique process portions to the corresponding DRAM-IF modules configured as special-purpose modules.

The special-purpose module unit 211 includes various IF modules formed as special-purpose modules, which execute exceptional processes to be executed in different state transitions from each other, by the common sequence unit 210. In particular, the special-purpose module unit 211 includes an SDR-IF module 211-0, a DDR-IF module 211-1, a DDR2-IF module 211-2, . . . , and a DDR(n)-IF module 211-n.

In the DRAM interface module group 21-1, an IF selector block of the selector 23 selects a RAM mode in accordance with system control setting information Cmd, and the common state transition portion 2102 of the common sequence unit 210 determines an IF module of the special-purpose module unit 211 to be used in combination.

The SDR-IF module 211-0, DDR-IF module 211-1, DDR2-IF module 211-2, . . . , DDR(n)-IF module 211-n, SRAM-IF module 21-2, DPRAM-IF module 21-3 and FIFO-IF module 21-4 carry out inputting and outputting at timings required by the memory controller 100 so that the semiconductor memory device 1 may operate as memories of the individually corresponding memory types.

For example, the SDR-IF module 211-0 carries out processing so that writing/reading accessing operations for the RAM array 30 may be operations of an SDR as viewed from the external memory controller 100. Meanwhile, the DDR-IF module 211-1 carries out processing so that writing/reading accessing operations for the RAM array 30 may be operations of a DDR as viewed from the external memory controller 100.

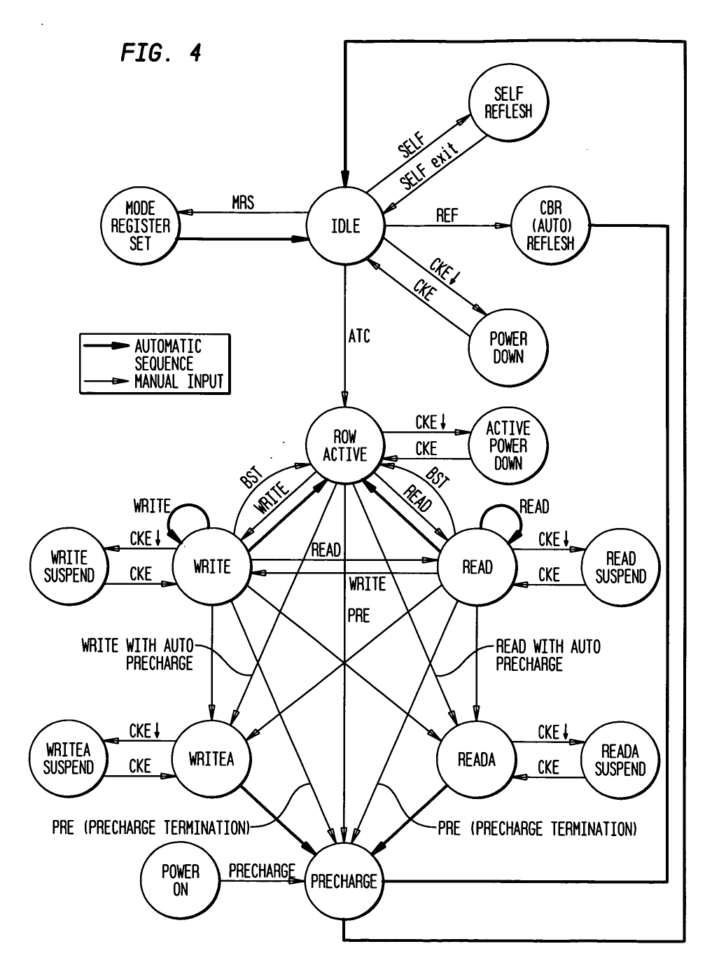

The reason why the DRAM interface module group 21-1 of the interface module group 21 is divided into the common sequence unit 210 and the special-purpose module unit 211 in such a manner as described above is described below with reference to FIGS. 4 to 7.

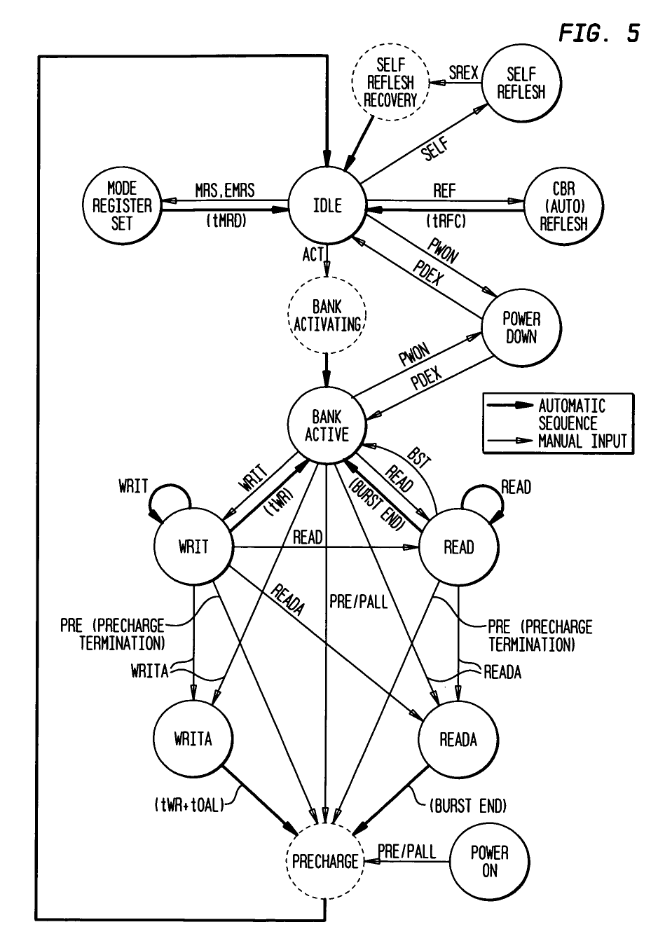

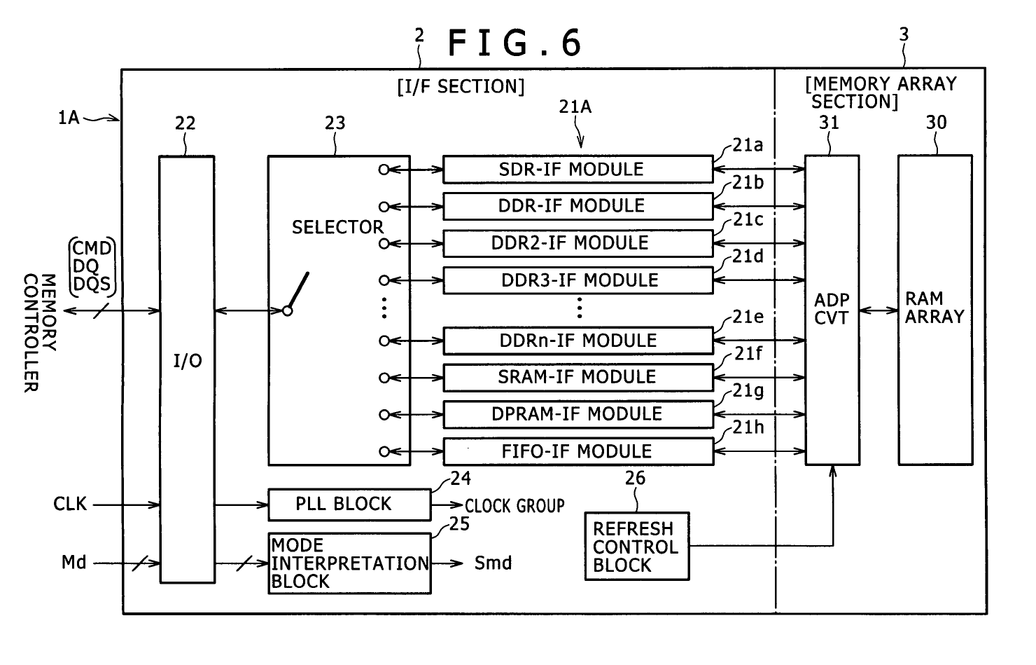

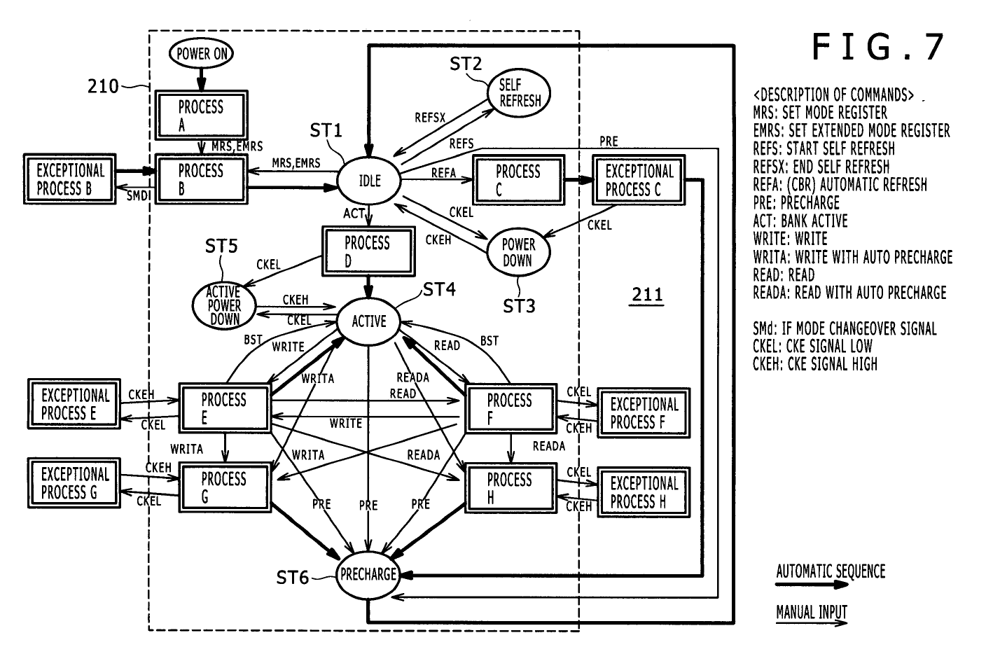

FIGS. 4 and 5 illustrate state transitions of the SDRAM and the DDR-SDRAM, respectively. Meanwhile, FIG. 6 shows an example of a configuration of a semiconductor memory device wherein IF modules are provided without providing a common sequence unit and a special-purpose module unit separately from each other. FIG. 7 illustrates state transitions of a DRAM-IF module group where a common sequence unit and a special-purpose module unit are provided.

An existing memory, for example, an existing SDRAM, exhibits such state transitions as illustrated in FIG. 4. In this instance, the state is changed by a combination of inputted command signals to carry out writing or reading of data, precharge, refresh and so forth.

Similarly, a DDR-SDRAM exhibits such state transitions as illustrated in FIG. 5.

In such a multi-IF RAM which has, in one package, an SDR-IF module 21a, a DDR-IF module 21b, a DDR2-IF module 21c, a DDR3-IF module 21d, . . . , a DDR(n)-IF module 21e, an SRAM-IF module 21f, a DPRAM-IF module 21g and a FIFO-IF module 21h as shown in FIG. 6, the individual IF modules carry out processing in different state transitions from each other.

Therefore, it is necessary for the multi-IF RAM to have a number of state transitions equal to the number of IF modules which the multi-IF RAM has. And this may cause an increased circuit size.

It is to be noted that the semiconductor memory device 1A of FIG. 6 has such a configuration and functions as described above and as hereinafter described except that it is different only in the configuration of the interface module group 21 from the semiconductor memory device 1 of FIG. 3.

In the present embodiment, the multi-IF RAM having a plurality of IF modules in the inside of an IC forms those of state transitions of the IF modules which are common among the IF modules as a common sequence and forms those of the state transitions in which different processes are carried out among the IF modules as special-purpose modules of exceptional processes as seen in FIGS. 3, 4 and 7.

This implements simplification of the state transition circuit of the multi-IF RAM.

An example of operation of the common sequence unit and the special-purpose module units in the state transition diagram of FIG. 7 is hereinafter described in detail.

The PLL block 24 produces various processing clocks CK to be used by the SDR-IF module 211-0, DDR-IF module 211-1, DDR2-IF module 211-2, . . . , DDR(n)-IF module 211-n, SRAM-IF module 21-2, DPRAM-IF module 21-3 and FIFO-IF module 21-4 of the interface module group 21 based on the system clock CLK supplied thereto, for example, from the memory controller 100 and outputs the processing clocks CK to the interface module group 21.

Clock production of the PLL block 24 is hereinafter described in more detail.

The mode interpretation block 25 carries out interpretation of a logic value of the mode designation signal Md inputted thereto to decide a mode required for operation of the semiconductor memory device 1. Then, the mode interpretation block 25 outputs a mode signal Smd representative of the decided mode to pertaining blocks.

The refresh control block 26 has a function of issuing a refresh command within a refresh cycle and can thereby eliminate the necessity for an external refresh command.

The refresh control block 26 has a function of controlling so that a write command, a read command and a refresh command may not collide with each other and another function of skipping a refresh command with regard to a row address for which writing or reading is carried out within a refresh cycle.

The refresh control is hereinafter described in detail.

In the present semiconductor memory device 1, the IO buffer 22, selector 23, PLL block 24 and interface module group 21 carry out required operation in accordance with the mode signal Smd outputted from the mode interpretation block 25 such that the semiconductor memory device 1 functions as a memory of a particular memory type as viewed, for example, from the external memory controller 100.

It is assumed here that, where the memory controller 100 and the semiconductor memory device 1 are mounted on a circuit board of a certain electronic apparatus as seen in FIG. 1A, the memory controller 100 carries out a memory control process for the DDR2.

In this instance, a mode designation signal Md representative of the mode of the memory type of the DDR2 is inputted as a setting of the dip switch or a signal from the memory controller 100 to the mode interpretation block 25.

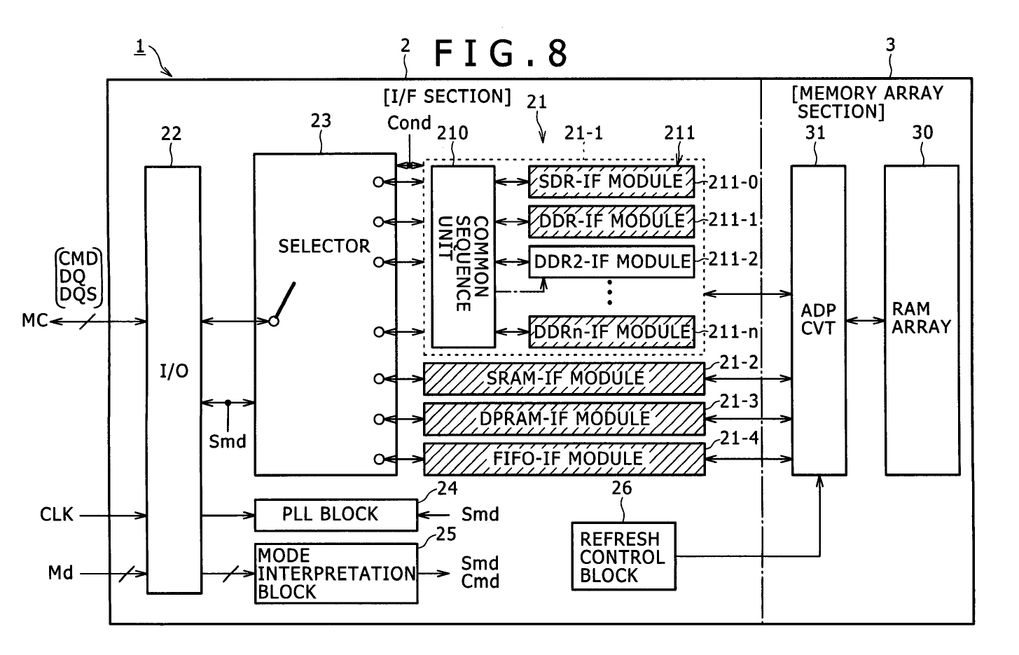

Operation of the semiconductor memory device 1 in this instance is illustrated in FIG. 8. The mode interpretation block 25 outputs the mode signal Smd representative of the DDR2 mode and system control setting information Cmd.

As hereinafter described, the IO buffer 22 changes over internal electric characteristics thereof, for example, a power supply potential and a delay characteristic, into those corresponding to the DDR2 in response to the mode signal Smd.

The selector 23 is placed into a state for selection of the DDR2-IF module 211-2 corresponding to the DDR2 in response to the mode signal Smd and the system control setting information Cmd.

The PLL block 24 produces a processing clock group for the DDR2-IF module group 211-2 in response to the mode signal Smd and supplies the produced processing clock group to the DDR2-IF module 211-2.

The PLL block 24 stops supply of the processing clock to the other interface modules (211-0, 211-1, 211-n, 21-2, 21-3 and 21-4).

Consequently, the semiconductor memory device 1 operates as a DDR2 as viewed from the memory controller 100. In particular, the memory controller 100 outputs a command CMD for control of the DDR2 and handles the input/output data DQ and the data strobe signal DQS at a timing of the DDR2.

In this instance, the DDR2-IF module 211-2 carries out writing/reading into/from the RAM array 30 in response to the command CMD from the memory controller 100. Meanwhile, the DDR2-IF module 211-2 cooperates with the common sequence unit 210 to carry out inputting/outputting to/from the memory controller 100 at a timing of the DDR2 thereby to implement an accessing operation having no trouble to the memory controller 100.

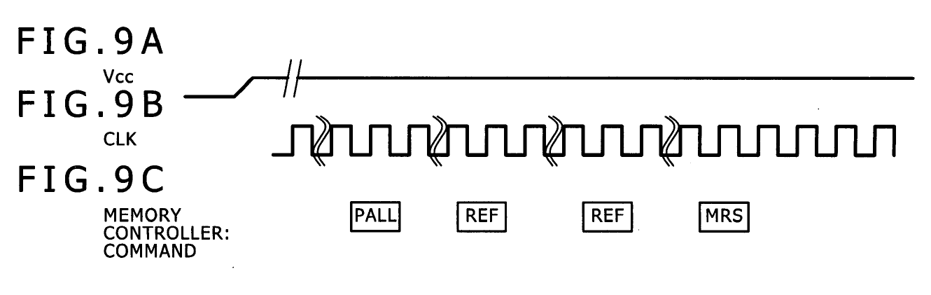

Now, an example of operation of the common sequence unit and the special-purpose module units in the state transition view of FIG. 7 is described with reference to FIGS. 9A to 14B.

Here, taking the SDR-IF as an example, a state transition in initialization, a state transition in writing, a state transition in writing with automatic precharge, a state transition in reading, a state transition in reading with automatic precharge and a state transition in automatic refresh (REF) are described.

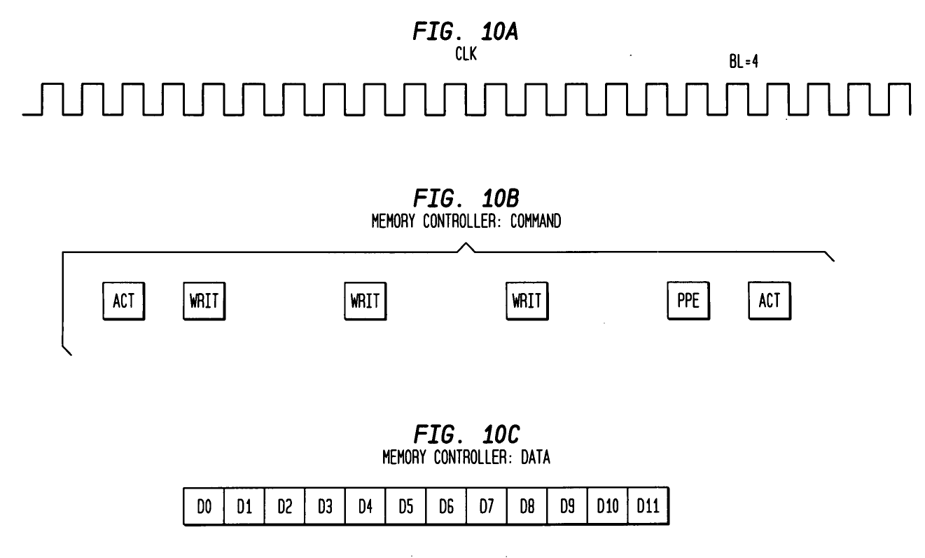

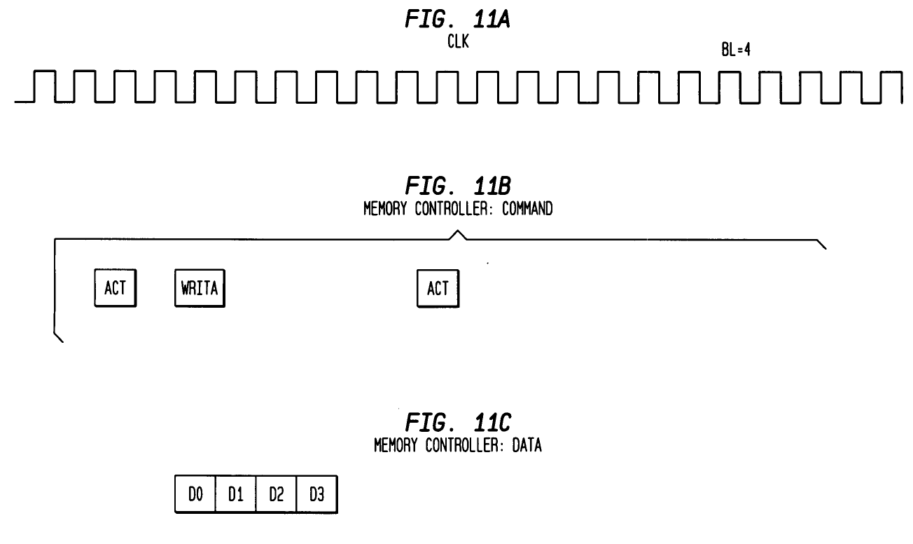

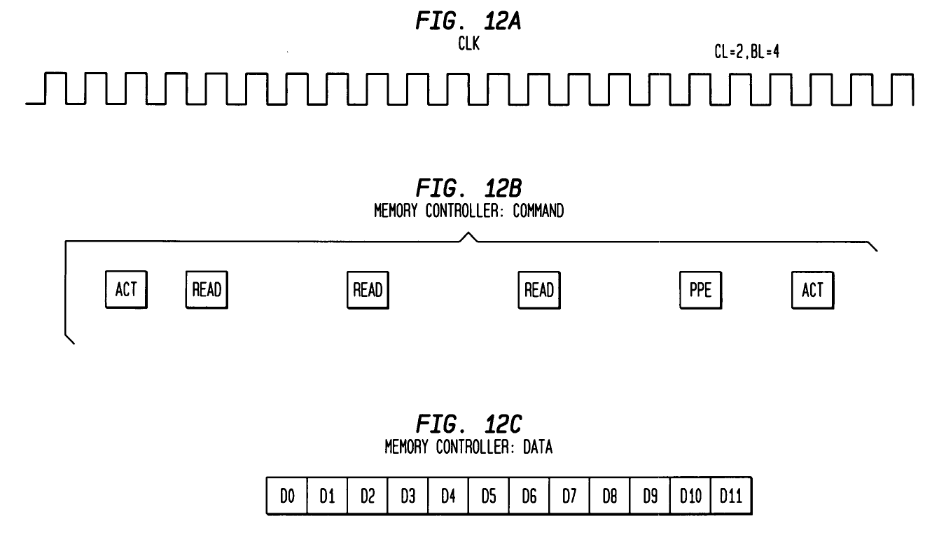

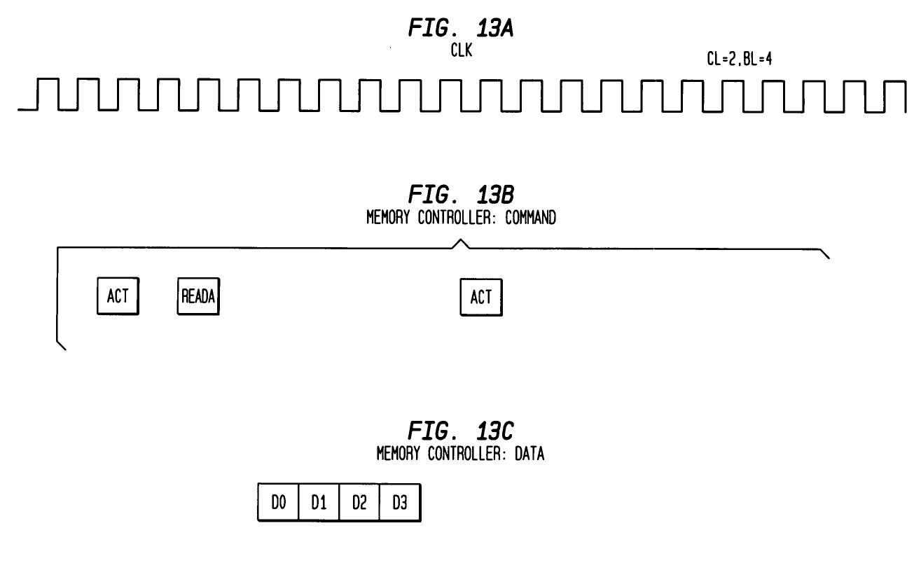

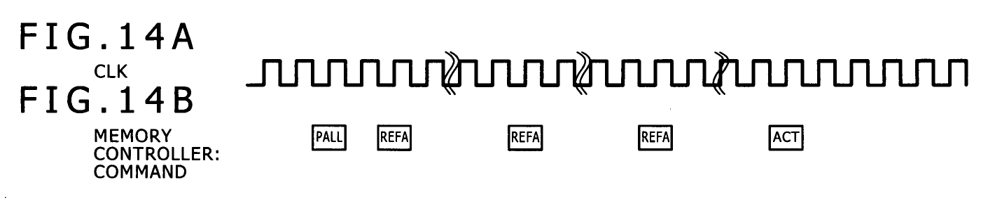

FIGS. 9A to 9C illustrate state transitions in initialization, and FIGS. 10A to 10C illustrate state transitions in writing while FIGS. 11A to 11C illustrate state transitions in writing with automatic precharge. FIGS. 12A to 12C illustrate state transitions in reading out while FIGS. 13A to 13C illustrate state transitions in reading with automatic precharge, and FIGS. 14A and 14B illustrate state transitions in automatic refresh (REF).

Meanwhile, such various commands as described below appear in FIG. 7.

In particular, MRS denotes a mode register setting command, EMRS an extended mode register setting command, REFS a self refresh starting command, REFSX a self refresh ending command, REFA a (CBR) automatic refresh command, PRE a precharge command, ACT a bank active command, WRITE a write command, WRITA a write command with automatic precharge, READ a read command, and READA a read command with automatic precharge.

Further, SMd denotes an IF mode changeover signal, CKEL represents that the CKE signal has the low level, and CKEH represents that the CKE signal has the high level.

First, the state transition in initialization is described with reference to FIGS. 9A to 9C.

FIG. 9A indicates a power supply voltage Vcc, FIG. 9B indicates the system clock CLK, and FIG. 9C indicates various commands from the memory controller 100.

Where initialization is carried out in such time charts as seen in FIGS. 9A to 9C, such a state transition as described below occurs.

After power is made available, a process A of the common sequence unit 210 is carried out. In the process A, an initialization sequence of the RAM array 30 is carried out.

The commands including the PALL command, refresh command REF, refresh command REF and mode register setting command MRS are successively inputted from the memory controller 100, and when the mode register setting command MRS among the commands is detected, another process B is entered.

In the process B, mode setting detection of the burst length (BL), lap time and CAS latency (CL) is carried out.

Although an exceptional process B is entered in the case of the DDR, DDR2 and so forth for carrying out DLL (delay locked loop) setting or the like, the SDR-IF automatically enters an idle (IDLE) state ST1 after the process B.

Now, a state transition upon writing is described with reference to FIGS. 10A to 10C.

FIG. 10A illustrates the system clock CLK, FIG. 10B illustrates various commands from the memory controller 100, and FIG. 10C illustrates write data from the memory controller 100.

Where writing is carried out in such time charts as seen in FIGS. 10A to 10C, such a state transition as described below occurs.

From the idle state ST1, one of the process B, a self refresh (Self Refresh) state ST2, a process C, a power down (Power Down) state ST3 and a process D is entered in accordance with the command detected by the command detection portion 2101.

If, in the idle state ST1, the bank active command ACT is received, then the process D is entered. The IF changeover signal SMd is received in the process D, and it is decided based on the IF changeover signal SMd whether an active (ACTIVE) state ST4 should be entered or an active power down (ACTIVE POWER DOWN) state ST5 should be entered. The SDRAM directly enters the active state ST4.

In the active state ST4, the active power down state ST5, a process E, another process F, a further process G, a still further process H or a precharge (Precharge) state ST6 is entered.

If the write command WRITE is received in the active state ST4, then the process E is entered. In the process E, a writing process into the RAM array 30 is carried out.

After the writing process ends, the active state ST4 is entered automatically. If the write command WRITE is inputted successively, then the state transition described is repeated.

If the precharge command PRE is received in the process E, then the precharge state ST6 is entered and then the state transition is carried out up to the idle state ST1.

In the process E, a signal CKEL is received and a write suspended state is entered as the exceptional process E. However, this occurs only with the SDRAM, and in any other IF mode, the exceptional process E is not entered. If the signal CKEH is received in the exceptional process E, then the state of the process E is entered.

Now, a state transition upon writing with automatic precharge is described with reference to FIGS. 11A to 11C.

FIG. 11A illustrates the system clock CLK, FIG. 11B illustrates various commands from the memory controller 100, and FIG. 11C illustrates write data from the memory controller 100.

Where writing is carried out in such time charts as seen in FIGS. 11A to 11C, such a state transition as described below occurs.

If the bank active command ACT is received in the idle state ST1, then the process D is entered. In the process D, the IF changeover signal SMd is received and it is decided whether or not the active state ST4 should be entered or the active power down state ST5 should be entered. The SDRAM directly enters the active state ST4.

In the active state ST4, one of the active power down state ST5, process E, process F, process G, process H and precharge state ST6 is entered.

If the write command WRITA with automatic precharge is received in the active state ST4, then the process G is entered. In the process G, a writing process into the RAM array 30 is carried out. After the writing process ends, the precharge state ST6 is entered automatically, and the state transition occurs up to the idle state ST1.

In the process G, the signal CKEL is received and the write suspended state is entered as the exceptional process G. However, this occurs only with the SDRAM, but the exceptional process G is not entered in the case of any other IF mode. On the other hand, if the signal CKEH is received in the exceptional process G, then the state of the process G is entered.

Now, a state transition upon reading out is described with reference to FIGS. 12A to 12C.

FIG. 12A illustrates the system clock CLK, FIG. 12B illustrates various commands from the memory controller 100, and FIG. 12C illustrates read data from the memory controller 100.

Where reading is carried out in such time charts as seen in FIGS. 12A to 12C, such a state transition as described below occurs.

If the bank active command ACT is received in the idle state ST1, then the process D is entered. In the process D, the IF changeover signal SMd is received and it is decided whether or not the active state ST4 should be entered or the active power down state ST5 should be entered. The SDRAM directly enters the active state ST4.

In the active state ST4, one of the active power down state ST5, process E, process F, process G, process H and precharge state ST6 is entered.

If the read command READ is received in the active state ST4, then the process F is entered. In the process F, a reading out process from the RAM array 30 is carried out. After the reading out process ends, the active state ST4 is entered automatically. If the read command READ is inputted successively, the state transition described above is repeated.

If the precharge command PRE is received in the process F, then the precharge state ST6 is entered, and the state transition occurs up to the idle state ST1 automatically.

In the process F, the signal CKEL is received and the read suspended state is entered as the exceptional process F. However, this occurs only with the SDRAM, but the exceptional process F is not entered in the case of any other IF mode. On the other hand, if the signal CKEH is received in the process F, then the state of the process F is entered.

Now, a state transition upon reading out with automatic precharge is described with reference to FIGS. 13A to 13C.

FIG. 13A illustrates the system clock CLK, FIG. 13B illustrates various commands from the memory controller 100, and FIG. 13C illustrates read data from the memory controller 100.

Where reading out with automatic precharge is carried out in such time charts as seen in FIGS. 13A to 13C, such a state transition as described below occurs.

If the bank active command ACT is received in the idle state ST1, then the process D is entered. In the process D, the IF changeover signal SMd is received and it is decided whether or not the active state ST4 should be entered or the active power down state ST5 should be entered. The SDRAM directly enters the active state ST4.

In the active state ST4, one of the active power down state ST5, process E, process F, process G, process H and precharge state ST6 is entered.

If the read command READA with automatic precharge is received in the active state ST4, then the process H is entered. In the process H, a reading out process from the RAM array 30 is carried out. After the reading out process ends, the precharge state ST6 is entered automatically, and the state transition occurs up to the idle state ST1.

In the process H, the signal CKEL is received and the read suspended state is entered as the exceptional process H. However, this occurs only with the SDRAM, but the exceptional process H is not entered in the case of any other IF mode. On the other hand, if the signal CKEH is received in the exceptional process H, then the state of the process H is entered.

Now, a state transition upon automatic refresh is described with reference to FIGS. 14A and 14B.

FIG. 14A illustrates the system clock CLK, and FIG. 14B illustrates various commands from the memory controller 100.

Where automatic refresh is carried out in such time charts as seen in FIGS. 14A and 14B, such a state transition as described below occurs.

If the automatic refresh command REFA is received in the idle state ST1, then the process C is entered. In the process C, automatic refreshment (Auto Refresh) is carried out. After the automatic refreshment ends, the exceptional process C is entered immediately. However, in the case of the SDR-IF, nothing is carried out in the exceptional process C, and therefore, the precharge state ST6 is entered, whereafter the idle state ST1 is entered. If the automatic refresh command REFA is inputted successively, then the transition described above is repeated.

Since the DRAM interface module group 21-1 is configured such that those of state transitions of various DRAM-IF modules which are common among the DRAM-IF modules are formed as a common sequence and those of the state transitions in which different processes are carried out among the DRAM-IF modules are formed as special-purpose modules of exceptional processes, the circuit scale can be simplified by use of a common state transition.

Further, since the common state transition is used, the power consumption can be reduced.

Further, since the common sequence unit 210 and the special-purpose module unit 211 are provided separately, expansion of a special-purpose module can be coped with flexibly and readily.

Now, refresh control of the semiconductor memory devices 1 and 1A of FIGS. 2 and 6 is described.

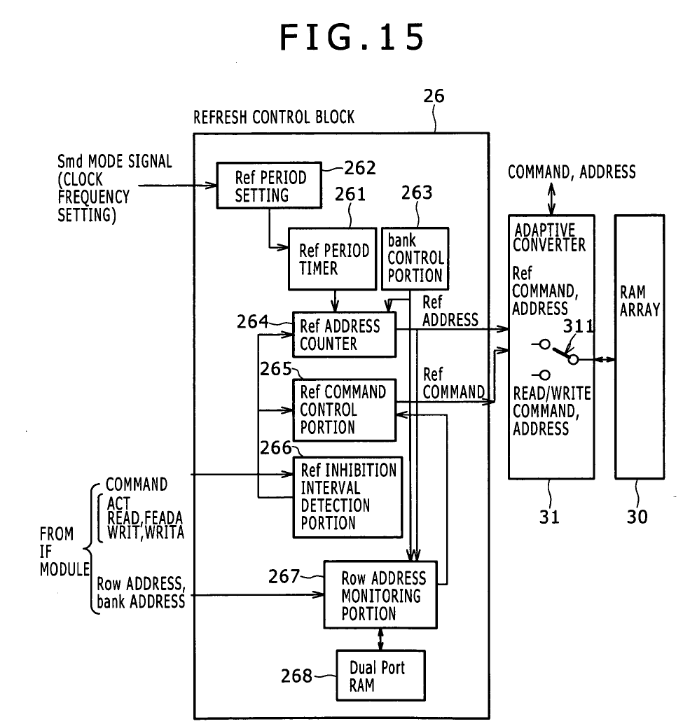

A particular configuration and functions of the adaptive converter (ADPCVT) 31 which can cope with a plurality of data widths are described with reference to FIGS. 15 to 25G.

It is to be noted here that description is given taking a process through the SDR-IF module 211-0 (or 21a in FIG. 6) as an example.

FIG. 15 shows an example of a configuration of the refresh control block and the adaptive converter of the semiconductor memory device 1.

The refresh control block 26 includes, where the semiconductor memory device 1 operates as a DRAM such as the SDRAM, DDR, DDR2, . . . , a circuit for eliminating the necessity for refresh control from the outside by executing refreshment between commands.

The refresh control block 26 issues a refresh address for each bank.

Further, since there is no necessity to execute a refresh operation for a row address accessed with the read command READ or the write command WRITE, the refresh control block 26 skips the address.

Referring to FIG. 15, the refresh control block 26 includes a refresh (Ref) cycle timer 261, a refresh (Ref) cycle setting portion 262, a bank control portion 263, a refresh address counter 264, a refresh (Ref) command control portion 265, a refresh inhibition interval detection portion 266, a row (Row) address monitoring portion 267, and a dual port RAM (Dual-Part-RAM) 268.

The refresh cycle timer 261 counts the refresh cycle. The refresh cycle timer 261 loads a maximum value of a counter suited for the clock operation frequency and clears the refresh (Ref) cycle counter when the value of the counter coincides with the maximum value.

Since the upper limit count value of the refresh cycle timer varies depending upon the difference in clock frequency, the upper limit value is set in advance to the refresh cycle setting portion 262. A plurality of upper limit values are prepared in advance and selectively used in accordance with a mode signal from the outside.

The bank control portion 263 has a circuit for toggling the refresh address counter with a number equal to the number of banks of the RAM array 30.

The refresh address counter 264 functions as a counter for supplying a refresh address to the RAM array 30.

The refresh address counter 264 stops counting up of the address within a cycle within which refreshment is inhibited, but increments by a number corresponding to a row address of the RAM array 30.

Further, the refresh address counter 264 toggles by a number of times equal to the number of banks within a refresh cycle.

The refresh command control portion 265 supplies a refresh command to the RAM array 30. Where a refresh command is to be issued to an address of the same bank whose address has been accessed for reading or writing within a period of a refresh cycle, the refresh command control portion 265 skips the command.

The refresh inhibition interval detection portion 266 detects a command inputted thereto such as, for example, the bank active command ACT, read command READ, read command READA with automatic precharge, write command WRITE or write command WRITA with automatic precharge and sets a flag for stopping issuance of the refresh command REF within a period of several clocks.

If the RAM array 30 is accessed with the read command READ or the write command WRITE, then no refreshment is required for the row address within a refresh period. Therefore, the row address monitoring portion 267 monitors the row address accessed for reading or writing, and outputs a flag for skipping the refresh command REF if double accessing is to be carried out within a refresh cycle.

The row address monitoring portion 267 stores information of a row address accessed within a refresh cycle, for example, into the dual port RAM 268.

The row address monitoring portion 267 reads out information stored in the dual port RAM 268 at a timing of a refresh address and outputs a skip flag if the read out information is information of a row address accessed once. The row address monitoring portion 267 clears the read out information for next reading.

The RAM array 30 is formed as a memory array which requires a refresh operation.

The adaptive converter 31 has a changeover circuit 311 for changing over among an address ADR from an IF module, a command CMD for reading, writing or the like and an address RADR from the refresh control block 26, and a refresh command RE.

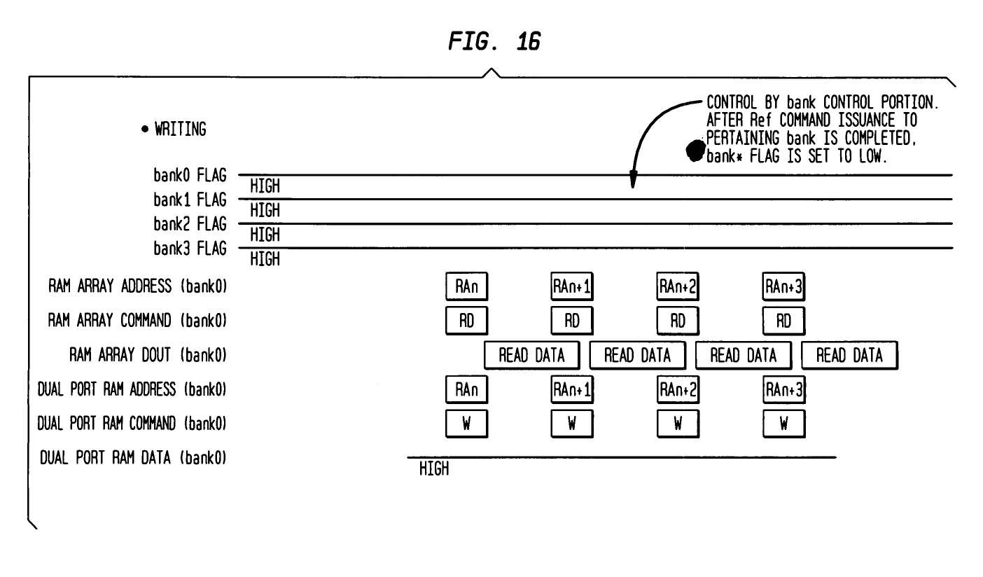

Here, row address monitoring, writing, reading and clearing operations under the control of the refresh control block 26 are described with reference to FIGS. 16 to 18.

FIG. 16 illustrates a writing operation under the control of the refresh control block 26.

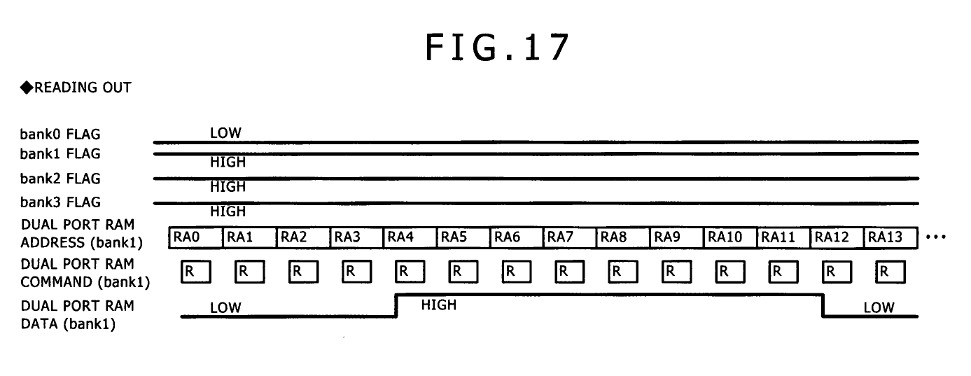

FIG. 17 illustrates a reading operation under the control of the refresh control block 26.

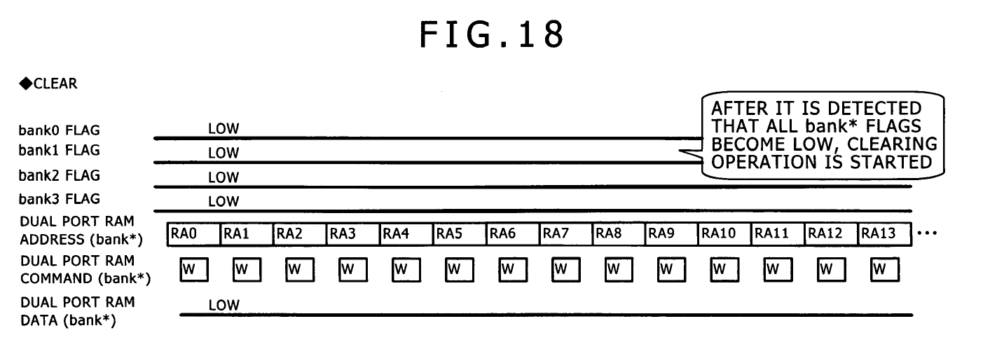

FIG. 18 illustrates a clearing operation under the control of the refresh control block 26.

### [Row Address Monitoring]

The row address monitoring portion 267 in the refresh control block 26 outputs a flag for skipping the refresh command REF.

The dual port RAM 268 is prepared for each bank.

### [Writing]

The refresh control block 26 determines a row address to be accessed with the read command READ or the write command WRITE of an SDR command as a write address of the dual port RAM 268 and writes “high” data into the address.

Even if the read command READ or the write command WRITE is issued after the refresh command REF to the pertaining bank is issued, writing into the address is not carried out.

Then, if the issuance of the refresh command REF to the pertaining bank is completed, then a bank*flag is placed into a low state under the control of the bank control portion 263.

### [Reading]

The address RADR for the RAM array 30 is determined as a read address for the dual port RAM 268, and the data at the read address is read out.

Then, if, within a refresh cycle, writing into or reading out from the row address is carried out before refreshment for the pertaining bank is carried out, then the “high” level is read out, but if no such accessing is carried out, then the “low” level is read out. This read data is used as the skip flag.

### [Clearing]

At a point of time at which refreshment ends for each bank, the stored contents of the dual port RAM 268 are all cleared, that is, the “low” level is written into the dual port RAM 268.

The clearing is controlled so that all dual port RAMs 268 prepared individually for the banks are cleared at the same time.

In this instance, the clearing operation is started when it is detected that all bank*flags become the “low” level.

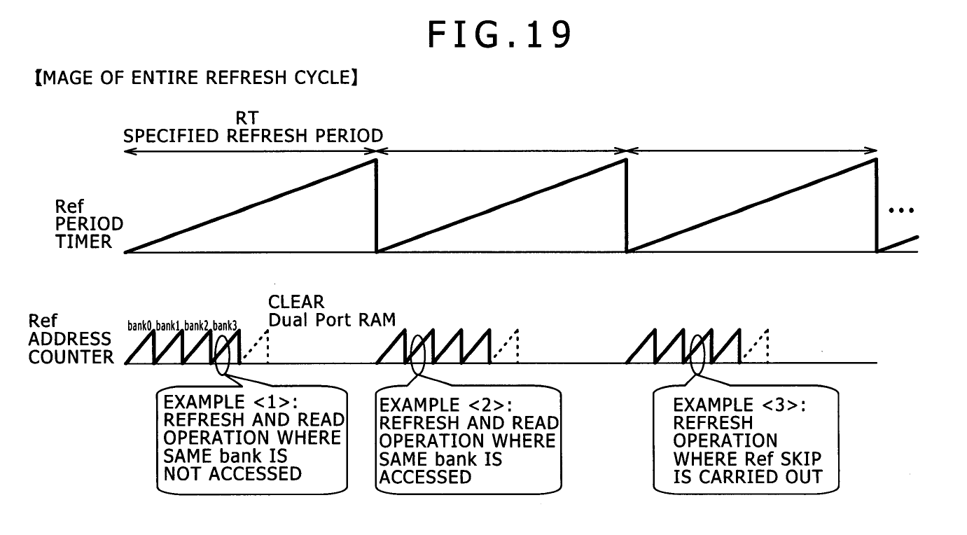

FIG. 19 illustrates a general image of a refresh cycle in the semiconductor memory device 1.

FIG. 19 shows three examples of refreshment, that is, first, second and third examples.

The first example is refresh and read operations wherein the same bank is not accessed.

The second example is refresh and read operations where the same bank is accessed.

The third example is a refresh operation where refresh skipping is carried out.

In the following, the first to third examples are described.

### First Example

The first example is refresh and read operations wherein the same bank is not accessed.

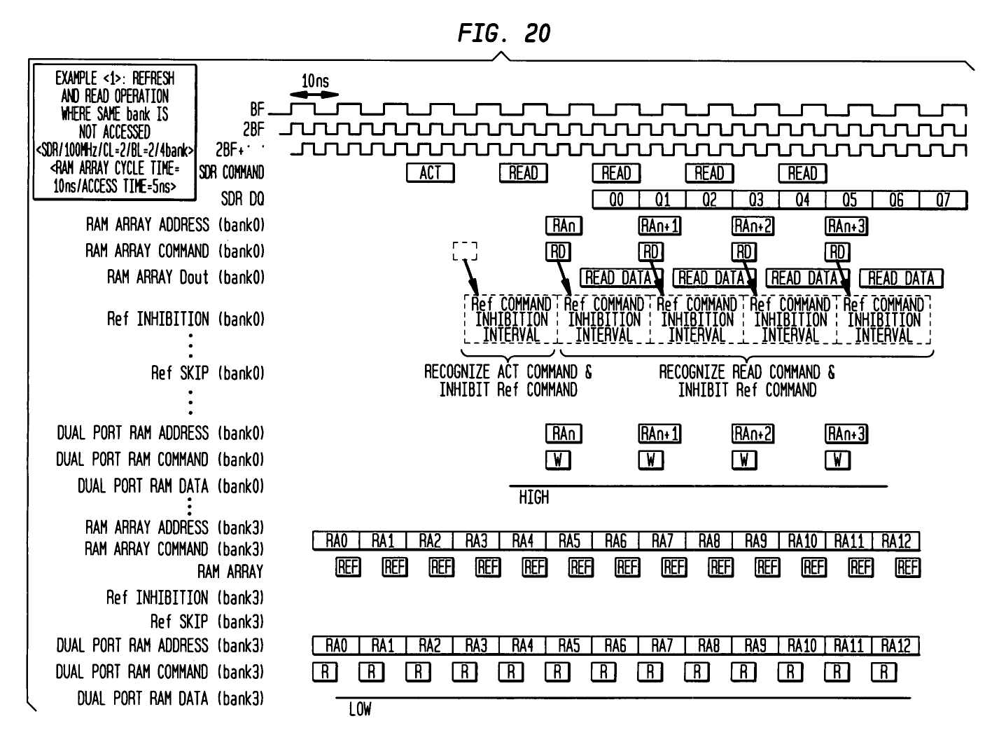

FIG. 20 illustrates the first example relating to a refresh operation.

In the present first example, the frequency of the SDR is 100 MHz; the CAS latency CL is CL=2; the burst length BL is BL=2; the cycle time of the RAM array 30 including four banks is 10 ns; and the access time is 5 ns.

In the first example, a bank of the RAM array 30 being accessed in accordance with the read command READ and a bank to be refreshed are different from each other, and therefore, the refresh operation is not interrupted.

In this instance, the bank active command ACT is recognized and the refresh command REF is inhibited.

The read command READ is recognized and the refresh command REF is inhibited.

### Second Example

The second example is refresh and read operations where the same bank is accessed.

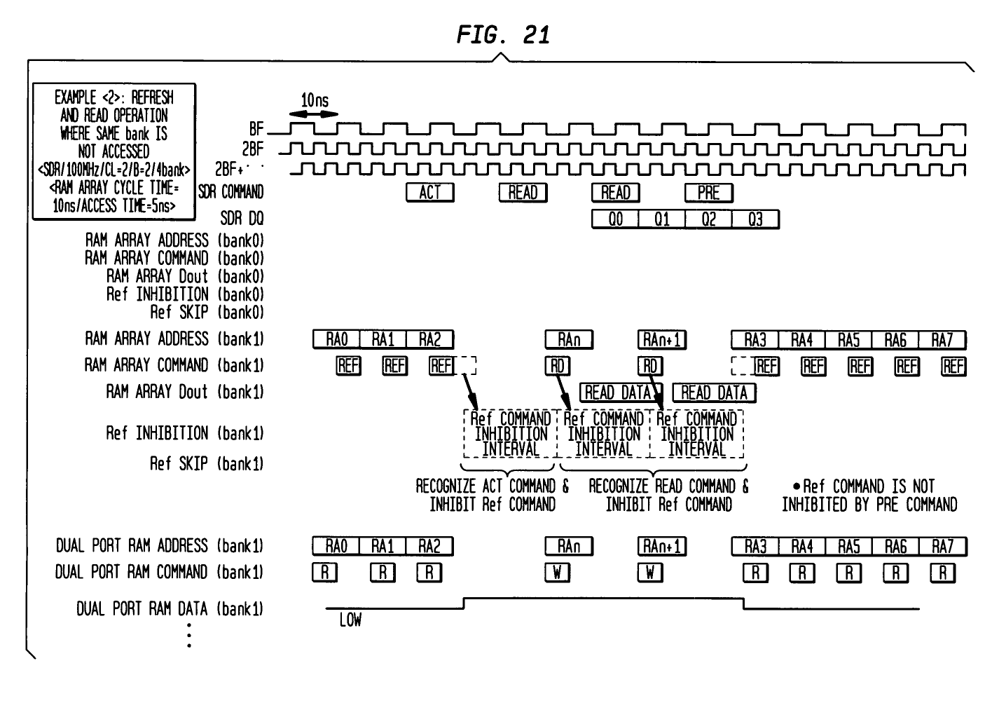

FIG. 21 illustrates the second example regarding a refresh operation.

Also in the second example, the frequency of the SDR is 100 MHz; the CAS latency CL is CL=2; the burst length BL is BL=2; the cycle time of the RAM array 30 including four banks is 10 ns; and the access time is 5 ns.

In the second example, since a bank of the RAM array 30 being accessed in accordance with the read command READ and a bank to be refreshed are same as each other, the refresh operation is interrupted.

In this instance, the bank active command ACT is recognized and the refresh command REF is inhibited.

The read command READ is recognized and the refresh command REF is inhibited.

Here, the refresh command REF is not inhibited by the precharge command PRE.

### Third Example

The third example is a refresh operation where refresh skipping is carried out.

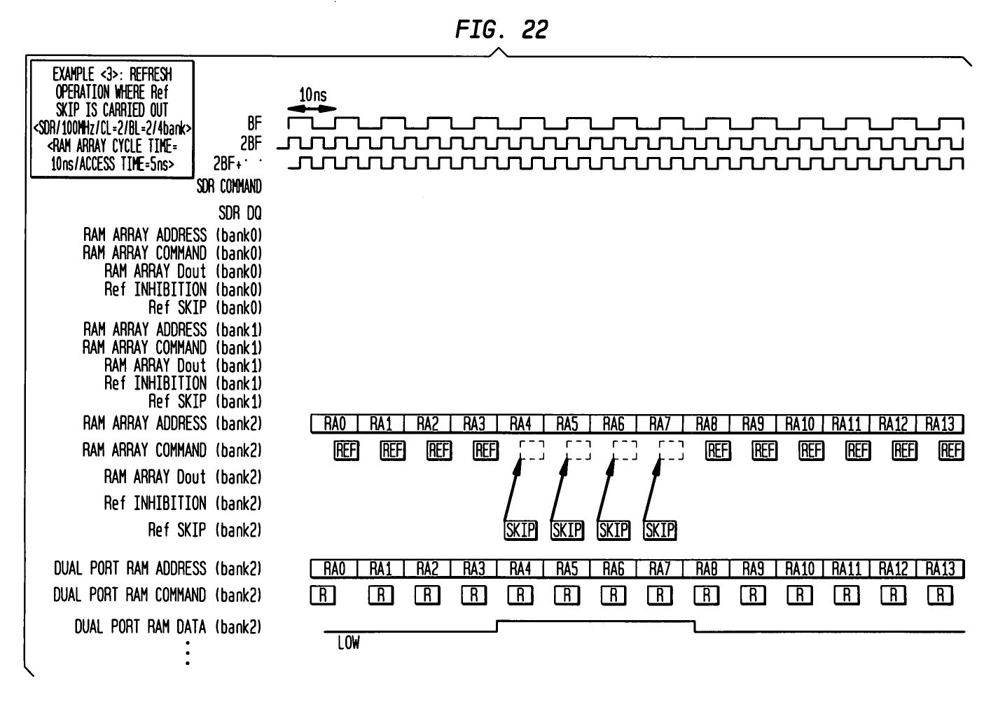

FIG. 22 illustrates the third example regarding a refresh operation. Also in the third example, the frequency of the SDR is 100 MHz; the CAS latency CL is CL=2; the burst length BL is BL=2; the cycle time of the RAM array 30 including four banks is 10 ns; and the access time is 5 ns.

In the third example, if a reading or writing process is carried out for a certain bank before the bank is refreshed, then the accessed row address is skipped.

As described above, where the semiconductor memory device 1 is to operate as a DRAM such as an SDRAM, a DDR, a DDR2, . . . , the refresh control block 26 includes a circuit which executes a refresh operation between commands to eliminate the necessity for refresh control from the outside, and has a function of issuing a refresh address for each bank and another function of skipping, since there is no necessity to execute a refresh operation for a row address accessed with the read command READ or the write command WRITE, the address.

Accordingly, a refresh command from the outside is not required, and a refresh operation can be carried out in response to an access situation. Consequently, efficient refresh control can be carried out, and hence efficient memory accessing can be carried out.

While each interface module implements inputting and outputting to and from the memory controller 100 at operation timings of a corresponding memory type as described above, operation of the SDR-IF module 211-0 corresponding to the SDR and the DDR-IF module 211-1 corresponding to the DDR is described as an example.

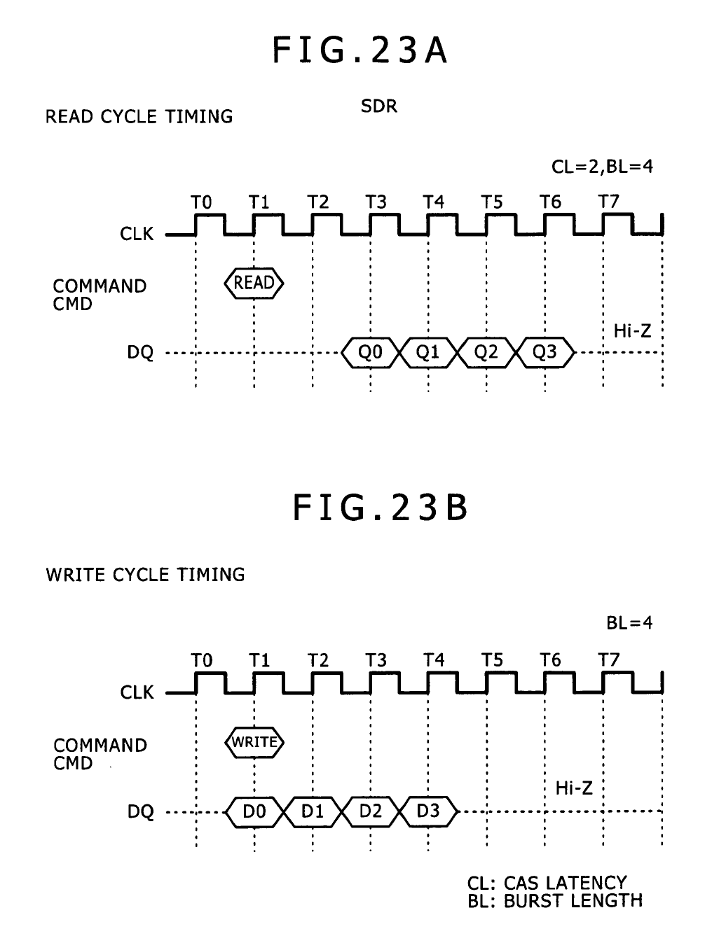

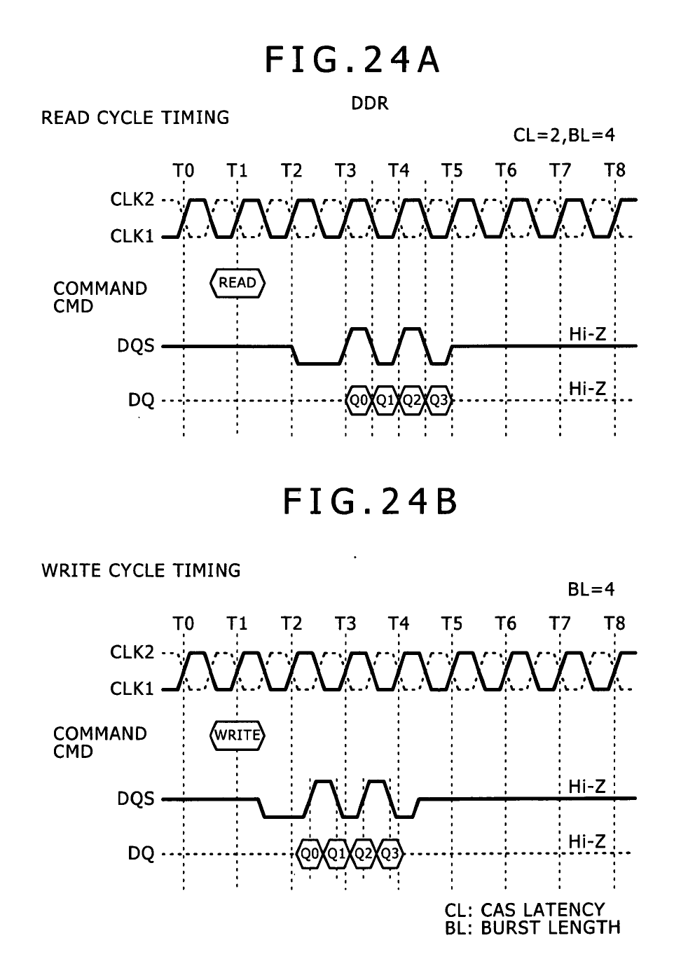

First, timings of reading/writing processes of the SDR and the DDR are described with reference to FIGS. 23A, 23B and 24A, 24B.

FIGS. 23A and 23B illustrate an example of a read cycle timing and a write cycle timing of an ordinary SDR-SDRAM. Particularly, FIGS. 23A and 23B illustrate an example of timings of the system clock CLK, command CMD and input/output data DQ where the CAS latency CL=2 and the burst length BL is 4.

The SDRAM latches each command (control signal) CMD at a rising edge of the system clock CLK inputted thereto and carries out inputting and outputting of data in synchronism with the system clock CLK. The timing of a rising edge of the system clock CLK is represented by T1, T2, . . . .

As a read cycle timing of FIG. 23A, the read command READ supplied from the host side, for example, from a memory control device corresponding to the memory controller 100 is latched at timing T1. Where the CAS latency CL is CL=2, data Q0, Q1, Q2 and Q3 read out in response to the read command READ are outputted to the host side after timing T3 later by 2 clocks.

As a write cycle timing of FIG. 23B, the write command WRITE supplied from the host side is latched, for example, at timing T1. Further, the data Q0, Q1, Q2 and Q3 supplied from the host side are latched after timing T1, and a writing process is carried out.

Meanwhile, FIGS. 24A and 24B illustrate an example of a read cycle timing and a write cycle timing of the DDR-SDRAM. Also in this instance, FIGS. 24A and 24B illustrate an example of timings of the system clocks CLK1 and CLK2, command CMD, input/output data DQ and data strobe signal DQS where the CAS latency CL=2 and the burst length BL is 4. The clock CLK2 is an inverted phase flock of the clock CLK1.

As with the SRD-SDRAM, the DDR-SDRAM receives a command at a rising edge of the system clock CLK inputted thereto and carries out control. However, the timings of data inputting and outputting are different from those of the SDR-SDRAM.

In order to implement high-speed data transfer, the DDR-SDRAM uses the clocks CLK1 and CLK2 having the opposite phases to each other and a data strobe signal DQS. The data strobe signal DQS is synchronized with the clock CLK1, and the input/output data DQ is synchronized with the opposite rising and falling edges of the data strobe signal DQS.

At a read cycle timing of FIG. 24A, a command process is carried out, for example, at a rising edge of the clock CLK1 as timing T1. Where the CAS latency CL is CL=2, read data is outputted after timing T3 later by 2 clocks. In this instance, the data Q0, Q1, Q2 and Q3 are outputted in synchronism with the opposite edges of the data strobe signal DQS.

On the other hand, at a write cycle timing of FIG. 24B, a write command supplied from the host side is latched, for example, at timing T1. Further, a writing process of the data Q0, Q1, Q2 and Q3 is carried out in synchronism with the opposite edges of the data strobe signal DQS.

It is to be noted that the DDR2, DDR3, . . . carry out operation similar to that of the DDR but are different in the CAS latency CL which can be selected and the operation frequency.

For example, some difference exists in the processing timing depending upon a difference in memory type such as the SDR and the DDR.

In the present semiconductor memory device 1, the IF modules of the interface module group 21 function in order to absorb such difference as descried above to allow the semiconductor memory device 1 to operate as memories of various memory types.

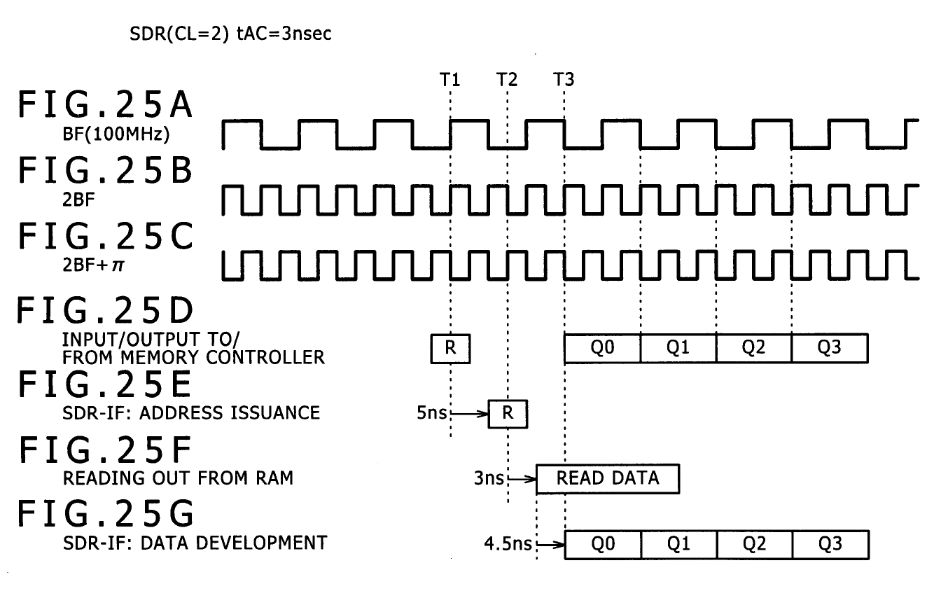

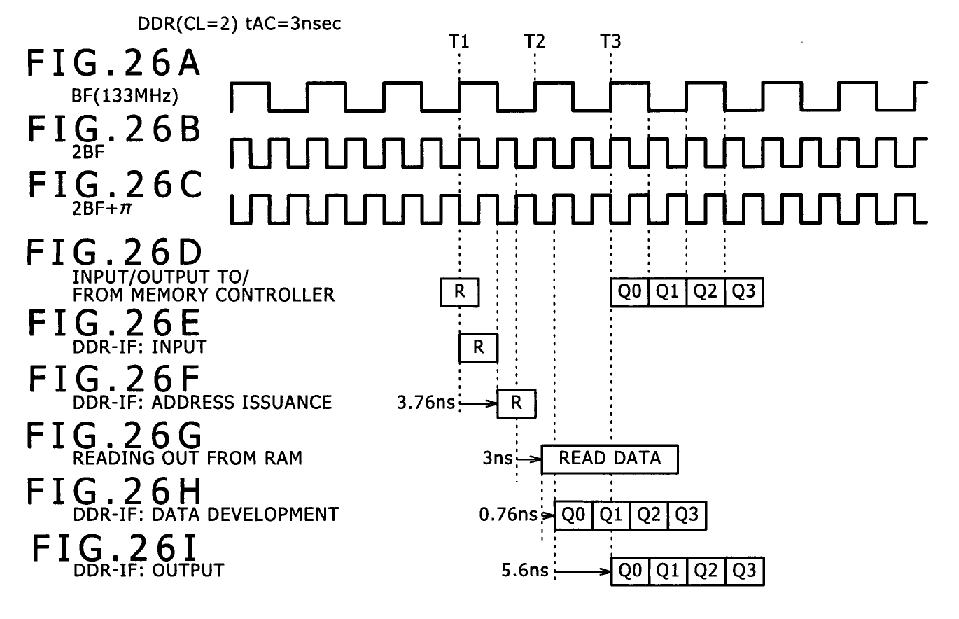

FIGS. 25A to 25G illustrate inputting and outputting operation timings where the SDR-IF module 211-0 functions, and FIGS. 26A to 26I illustrate inputting and outputting operation timings where the DDR-IF module 211-1 functions.

FIGS. 25A to 25G and 26A to 261 illustrate inputting and outputting operation timings taking a case wherein the RAM array 30 has a performance of access time tAC=3 nsec after an address is inputted until data is read out and outputted as an example. Further, the CAS latency CL is demanded to be CL=2.

FIGS. 25A to 25G illustrate timings where, for example, the memory controller 100 issues a reading request regarding the semiconductor memory device 1 as an SDR. In other words, the semiconductor memory device 1 is placed into the SDR mode such that the SDR-IF module 211-0 functions.

FIG. 25A illustrates a basic clock BF, which has a frequency set, for example, to 100 MHz. The basic clock BF is synchronized with the system clock CLK supplied from the memory controller 100 to the semiconductor memory device 1 and has a phase and a frequency same as those of the system clock CLK.

Meanwhile, a clock 2BF of FIG. 25B is a clock of a frequency equal to twice that of the basic clock BF, and a clock 2BF+π of FIG. 25C is an inverted clock having a phase shifted by 180° from that of the clock 2BF.

The clocks BF, 2BF and 2BF+π are produced by the PLL block 24 based on the system clock CLK inputted thereto and supplied as a processing clock group to the SDR-IF module 211-0.

FIG. 25D illustrates inputting and outputting to and from the memory controller 100 carried out through the IO buffer 22 by the SDR-IF module 211-0.

FIG. 25E illustrates a timing at which an address is issued from the SDR-IF module 211-0 to the RAM array 30, that is, to the adaptive converter 31.

FIG. 25F illustrates a timing at which read data from the RAM array 30 is transferred to the SDR-IF module 211-0.

FIG. 25G illustrates a timing at which the SDR-IF module 211-0 develops the read data and passes the data to the IO buffer 22.

It is assumed that, for example, at timing T1, a read command from the memory controller 100 is fetched. In this instance, the SDR-IF module 211-0 carries out a command interpretation process and a recognition process of a read address and then carries out issuance of an address to the RAM array 30 at timing T2 later by 5 nsec.

Since the access time tAC of the RAM array 30 is tAC=3 nsec, the read data is transferred to the SDR-IF module 21a after 3 nsec. Consequently, the SDR-IF module 211-0 develops and outputs the data Q0, Q1, Q2 and Q3.

In this instance, after timing T3 later by 4.5 nsec, the data Q0, Q1, Q2 and Q3 are developed at timings of rising edges of the basic clock BF and are outputted to the memory controller 100 through the IO buffer 22.

By such operations as described above, a reading operation equivalent to that of the SDR-SDRAM where the CAS latency CL is CL=2 is implemented by the semiconductor memory device 1.

In other words, the memory controller 100 may carry out command issuance regarding the semiconductor memory device 1 as an SDR. Meanwhile, the semiconductor memory device 1 carries out an operation as an SDR in response to the command by a required CAS latency by a process of the SDR-IF module 211-0.

It is to be noted that, while FIGS. 25A to 25G illustrate an operation in an example wherein the access time tAC of the RAM array 30 is tAC=3 nsec, where the access time tAC is long, this is coped with by raising the speed of the process of the SDR-IF module 211-0.

For example, if the access time tAC is tAC=5 nsec and the CAS latency CL=2 is required, then the SDR-IF module 211-0 carries out development and outputting of read data beginning with a timing later by 2.5 nsec thereby to make it possible to output the data Q0, Q1, Q2 and Q3 from timing T3.

On the other hand, if the access time tAC is tAC=8 nsec and the CAS latency CL=2 is required, then the SDR-IF module 211-0 carries out address issuance to the RAM array 30 after 2.5 nsec later than the latch of the read command at timing T1. Then, development and outputting of read data transferred after 8 nsec should be executed from timing T3 later by 2 nsec.

FIGS. 26A to 26I illustrate timings where the memory controller 100 issues a read request regarding the semiconductor memory device 1 as a DDR. In other words, FIGS. 26A to 26I illustrate timings where the semiconductor memory device 1 is placed into the DDR mode and the DDR-IF module 211-1 functions.

The basic clock BF of FIG. 26A is a clock having a phase and a frequency same as those of the system clock CLK supplied from the memory controller 100 to the semiconductor memory device 1. The frequency of the basic clock BF is set, for example, to 133 MHz.

Meanwhile, the clock 2BF of FIG. 26B is a clock of a frequency equal to twice that of the basic clock BF, and the clock 2BF+π of FIG. 25C is an inverted clock having a phase shifted by 180° from that of the clock 2BF.

The clocks BF, 2BF and 2BF+π are produced by the PLL block 24 based on the system clock CLK inputted thereto and supplied as a processing clock group to the DDR-IF module 211-1.

FIG. 26D illustrates inputting and outputting to and from the memory controller 100 carried out through the IO buffer 22 by the DDR-IF module 211-1.

FIG. 26E illustrates an address processing timing of the DDR-IF module 211-1.

FIG. 26F illustrates a timing at which the DDR-IF module 211-1 issues an address to the RAM array 30, that is, to the adaptive converter 31.

FIG. 26G illustrates a timing at which read data from the RAM array 30 is transferred to the DDR-IF module 211-1.

FIG. 26H illustrates a timing of a development process of the read data executed by the DDR-IF module 211-1.

FIG. 26I indicates a timing at which the DDR-IF module 211-1 passes the developed read data to the IO buffer 22.

It is assumed that, for example, at timing T1, a read command from the memory controller 100 is inputted. In this instance, the DDR-IF module 211-1 carries out an address process within a period of 3.76 nsec to carry out issuance of an address to the RAM array 30.

Since the access time tAC of the RAM array 30 is tAC=3 nsec, the read data is transferred to the DDR-IF module 211-1 after 3 nsec. Consequently, the DDR-IF module 211-1 develops the read data Q0, Q1, Q2 and Q3 after 0.76 nsec and outputs the read data Q0, Q1, Q2 and Q3 to the memory controller 100 through the IO buffer 22 at timings of both of rising edges and falling edges of the basic clock BF after timing T3 later by 5.6 nsec.

By such operations as described above, a reading operation equivalent to that of the DDR-SDRAM where the CAS latency CL is CL=2 is implemented by the semiconductor memory device 1.

In other words, the memory controller 100 may carry out command issuance regarding the semiconductor memory device 1 as a DDR. Meanwhile, the semiconductor memory device 1 carries out an operation as a DDR in response to the command by a required CAS latency by a process of the DDR-IF module 211-1.

It is to be noted that, while FIGS. 26A to 26I illustrate an operation in an example wherein the access time tAC of the RAM array 30 is tAC=3 nsec, where the access time tAC is long, this is coped with by raising the speed of the process of the DDR-IF module 21b.

While the reading operation timings where the SDR-IF module 211-0 and the DDR-IF module 211-1 operate are described above, also where the other interface modules such as the DDR2-IF module 211-2 functions, the reading operation timings may be set so that operation suitable for a corresponding memory type may be implemented.

In the case of the configuration of FIG. 2, one interface module functions in response to a mode suitable for a memory type so that the semiconductor memory device 1 can operate one of the SDR, DDR, DDR2 to DDR(n), SRAM, DPRAM and FIFO as viewed from the memory controller 100.

### 3. Mode Operation of the PLL Block

Incidentally, when the semiconductor memory device 1 operates as a memory of one of various memory types, the components thereof carry out processes suitable for the mode in response to the mode signal Smd from the mode interpretation block 25 as described above.

Particularly, the PLL block 24, selector 23 and IO buffer 22 carry out operation in accordance with the mode signal Smd. In the following, such mode operations are described.

Here, mode operations of the PLL block 24 are described.

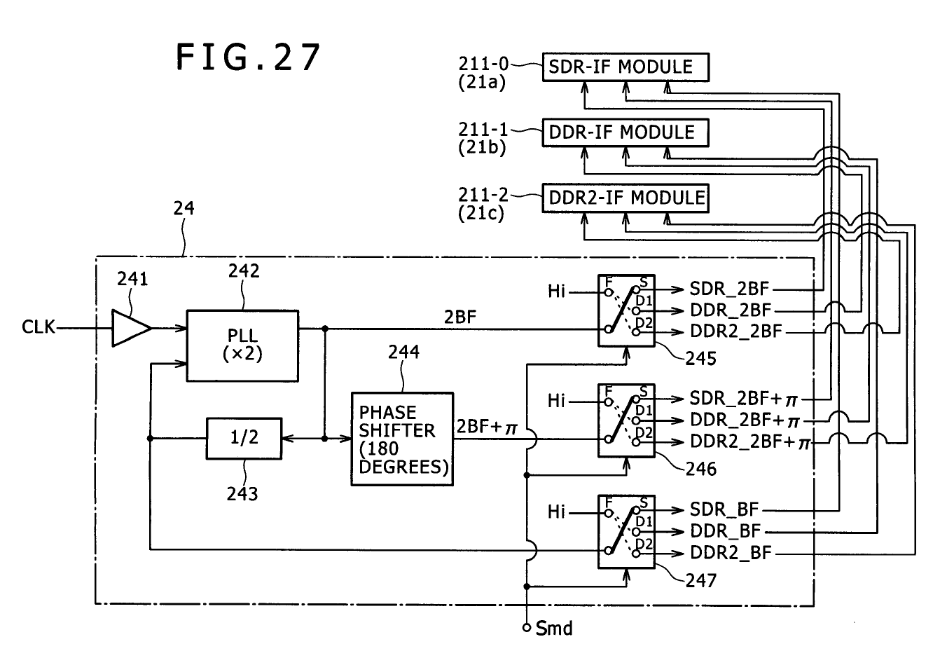

FIG. 27 shows an example of a particular configuration of the PLL block 24. It is to be noted that, for simplification in illustration and description, mode operation of the PLL block 24 is described referring only to those components which corresponding to three interface modules including the SDR-IF module 211-0, DDR-IF module 211-1 and DDR2-IF module 211-2 as a clock outputting system. Further, in FIG. 27, the common sequence unit 210 is omitted to facilitate understandings.

The system clock CLK supplied from the memory controller 100 is supplied to a clock producing PLL circuit 242 through a buffer amplifier 241. The clock producing PLL circuit 242 is formed as a PLL (Phase Locked Loop) circuit which includes, for example, a phase comparator, a loop filter, a VCO (Voltage-Controlled Oscillator) and a doubler.

The clock producing PLL circuit 242 carries out phase comparison between the system clock CLK and an output of a ½ divider 243 and outputs a clock 2BF of a double frequency synchronized with the system clock CLK. The clock 2BF is supplied to a changeover circuit 245.

Further, the clock 2BF is divided by the ½ divider 243 so as to have a frequency equal to that of the system clock CLK, and the resulting signal is fed back as a clock for phase comparison to the clock producing PLL circuit 242. Further, the clock divided by the ½ divider 243 is supplied as the basic clock BF having a phase and a frequency same as those of the system clock CLK to the changeover circuit 247.

Further, the clock 2BF outputted from the clock producing PLL circuit 242 is subjected to a phase shifting process by a phase shifter 244 to produce a clock 2BF+π of an inverted phase. This clock 2BF+π0 is supplied to a changeover circuit 246.

The changeover circuits 245, 246 and 247 have an S terminal, a D1 terminal and a D2 terminal.

The S terminal is connected to the SDR-IF module 211-0 or 21a.

The D1 terminal is connected to the DDR-IF module 211-1 or 21b.

The D2 terminal is connected to the DDR2-IF module 211-2 or 21c.

Further, the changeover circuits 245, 246 and 247 have a fixed voltage terminal F to which an H level voltage Hi is supplied. It is to be noted that the fixed voltage terminal F may otherwise be set to the L level voltage. Or, the process F may be placed into a high impedance state.

It is to be noted that, although the changeover circuits 245, 246 and 247 have three output terminals because FIG. 27 shows only the clock output system for the three interface modules (211-0, 211-1 and 211-2) as described hereinabove, actually the changeover circuits 245, 246 and 247 have output terminals provided also for the other interface modules (211-3 to 211-n, 21-2, 21-3 and 21-4) for selection.

The mode signal Smd from the mode interpretation block 25 is supplied to the changeover circuits 245, 246 and 247 of the PLL block 24 having such a configuration as described above. The changeover circuits 245, 246 and 247 change over the connection state in response to the mode signal Smd.

For example, if the mode signal Smd represents the SDR mode, then the changeover circuits 245, 246 and 247 select the S terminal thereof as an output terminal. The output terminals (D1 terminal, D2 terminal and other output terminals not shown) which are not selected in the mode are connected to the fixed voltage terminal F.

This state is illustrated in FIG. 27. In this state, the clocks 2BF, 2BF+π and BF are supplied as a processing clock group for the SDR-IF module 211-0 from the individual S terminals to the SDR-IF module 211-0.

For example, where the system clock CLK of 100 MHz is supplied from the memory controller 100, the basic clock BF of the 100 MHz illustrated in FIG. 25A and the clock 2BF and the clock 2BF+π of a double frequency illustrated in FIGS. 25B and 25C are supplied to the SDR-IF module 211-0.

As the processing clock group is supplied, the SDR-IF module 211-0 functions.

On the other hand, the DRAM interface module group 21-1 and the DDR2-IF module 211-2 (as well as the other interface modules 211-3 to 211-n, 21-2, 21-3 and 21-4 not shown) are placed into a state wherein no processing clock is supplied thereto, and the operation functions of them are placed into an off state.

On the other hand, for example, if the mode signal Smd indicates the DDR mode, then the changeover circuits 245, 246 and 247 select the D1 terminal thereof as an output terminal while the other output terminals (S terminal, D2 terminal and other output terminals not shown) are connected to the fixed voltage terminal F. Consequently, the clocks 2BF, 2BF+π and BF are supplied as a processing clock group for the DDR-IF module 211-1 from the individual D1 terminals to the DDR-IF module 211-1.

For example, where the system clock CLK of 133 MHz is supplied from the memory controller 100, the basic clock BF of the 133 MHz illustrated in FIG. 26A and the clocks 2BF and 2BF+π of a double frequency are supplied to the DDR-IF module 211-1.

Then, as the processing clock group is supplied, the DDR-IF module 211-1 functions while no processing clock is supplied to the SDR-IF module 211-0 and the DDR2-IF module 211-2 (as well as the other interface modules 211-3 to 211-n, 21-2, 21-3 and 21-4) and the operation functions of them are placed into an off state.

Where the PLL block 24 supplies clocks to the interface modules 211-0 to 211-n, 21-2, 21-3 and 21-4 in response to the mode signal Smd as described above, a required one of the interface modules functions while the other interface modules are placed into an off state wherein they do not operate.

### 4. Mode Operation of the Selector

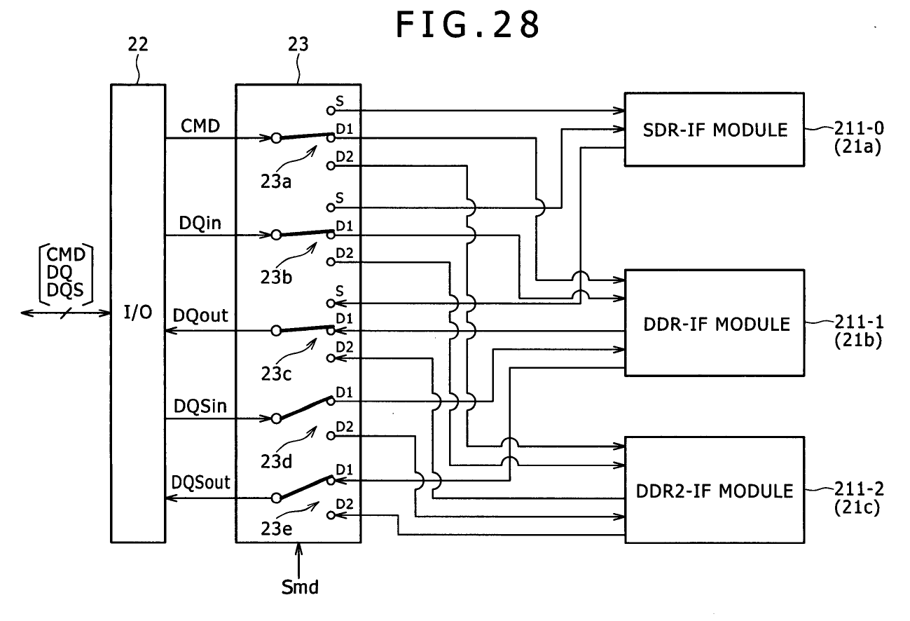

Mode operation of the selector 23 is described with reference to FIG. 28.

FIG. 28 shows only those components which correspond to the three interface modules including the SDR-IF module 211-0, DDR-IF module 211-1 and DDR2-IF module 211-2 similarly as in FIG. 27. Further, in FIG. 28, the common sequence unit 210 is omitted to facilitate understandings.

While inputting and outputting of the input/output data DQ and the data strobe signal DQS are carried out between the memory controller 100 and the IO buffer 22 as described hereinabove, as transfer of such signals by the IO buffer 22, transfer of the command CMD, a data input DQin, a data output DQout, a strobe signal input DQSin and a strobe signal output DQSout is carried out.

In particular, the selector 23 transfers the command CMD inputted from the memory controller 100 to the IO buffer 22 to the interface module group 21.

Where the command CMD is the write command, write data is inputted from the memory controller 100 to the IO buffer 22, and the selector 23 transfers the write data as the data input DQin to the interface module group 21.

On the other hand, where the command CMD is the read command, data is read out from the RAM array 30 by the interface module group 21, and the selector 23 transfers the read out data as the data output DQout to the IO buffer 22.

Further, where the mode is one of the DDR to the DDR(n), the data strobe signal DQS is used, and the selector 23 transfers an input and an output of the data strobe signal DQS as the strobe signal input DQSin and the strobe signal output DQSout, respectively.

The selector 23 includes selection switch circuits 23a to 23e corresponding to such signals as described above.

The selection switch circuit 23a corresponds to the command CMD and has an S terminal, a D1 terminal and a D2 terminal formed thereon as output terminals to the interface module group 21.

The selection switch circuit 23b corresponds to the data input DQin and has an S terminal, a D1 terminal and a D2 terminal formed thereon as output terminals to the interface module group 21.

The selection switch circuit 23c corresponds to the data output DQout and has an S terminal, a D1 terminal and a D2 terminal formed thereon as input terminals from the interface module group 21.

The selection switch circuit 23d corresponds to the strobe signal input DQSin and has a D1 terminal and a D2 terminal formed thereon as output terminals to the interface module group 21.

The selection switch circuit 23e corresponds to the strobe signal output DQSout and has a D1 terminal and a D2 terminal formed thereon as input terminals from the interface module group 21.

It is to be noted that, in FIG. 28, since only input and output systems to and from the three interface modules 211-0, 211-1 and 211-2 are shown, although output terminals or input terminals for the other interface modules 211-3 to 211-n, 21-2, 21-3 and 21-4 are not shown, actually output terminals and input terminals also for the other interface modules 211-3 to 211-n, 21-2, 21-3 and 21-4 are formed for selection.

The selection switch circuits 23a to 23e of the selector 23 select an output terminal or an input terminal in response to the mode signal Smd from the mode interpretation block 25.

For example, if the mode signal Smd represents the SDR mode, then the selection switch circuits 23a, 23b and 23c select the S terminal. It is to be noted that, in the SDR mode, since the data strobe signal DQS is not used, the selection switch circuits 23d and 23e may be in a non-connected state.

Consequently, transfer of the command CMD, data input DQin and data output DQout between the IO buffer 22 and the SDR-IF module 211-0 is implemented.

For example, where the mode signal Smd represents the DDR mode, the selection switch circuits 23a to 23e select the D1 terminal.

FIG. 28 illustrates the state just described, and in this state, transfer of the command CMD, data input DQin, data output DQout, strobe signal input DQSin and strobe signal output DQSout between the IO buffer 22 and the DDR-IF module 211-1 is implemented.

For example, where the selection switch circuits 23a to 23e of the selector 23 carry out connection selection in response to the mode signal Smd in such a manner as described above, signal transfer is carried out between one of the interface modules which is functioning and the IO buffer 22, and inputting and outputting of a signal are executed between the one functioning interface module and the memory controller 100.

### 5. Mode Operation of the IO Buffer

As mode operation of the IO buffer 22, changeover of the buffer power supply voltage characteristic or the delay characteristic in response to a mode, that is, a memory type to be executed, is carried out.

The buffer power supply voltage is different depending upon the memory type, and is 3.3 V or 2.5 V for the SDR mode, 2.5 V for the DDR mode, 1.8 V for the DDR2 mode, and 1.5 V for the DDR3. Accordingly, in the semiconductor memory device 1, changeover of the operation power supply voltage is required in response to the mode.

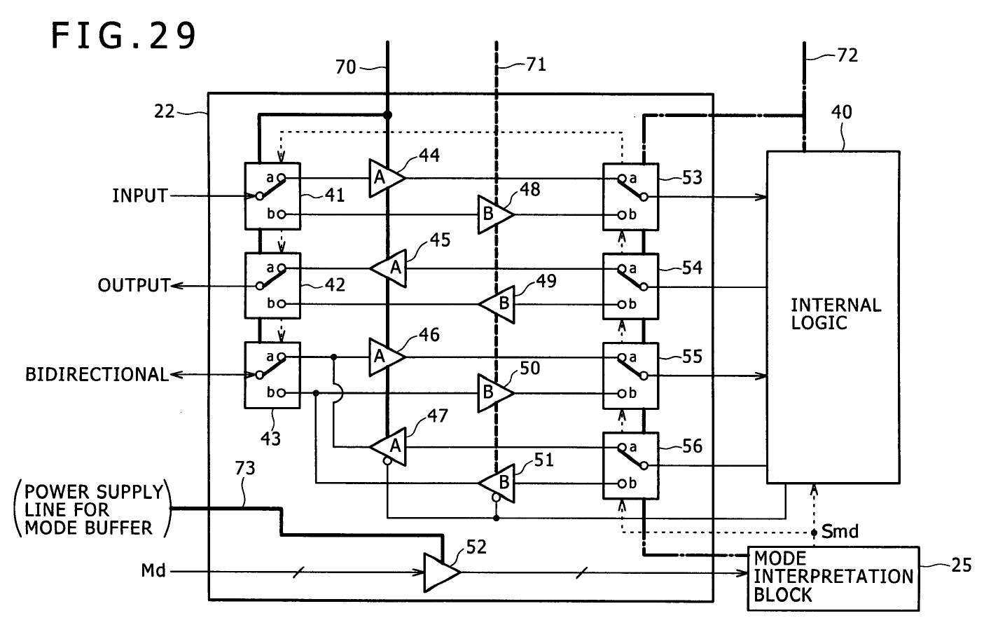

FIGS. 29 to 33 show examples of a configuration of the IO buffer 22 for changeover of the power supply voltage and the delay characteristic. In the figures, operation of changing over the power supply voltage is represented as two types including a type A and another type B. For example, a buffer amplifier denoted by “A” is of the type A whose delay characteristic is T1 with a power supply voltage of 3.3 V, and another buffer amplifier denoted by “B” is of the type whose delay characteristic is T2 with another power supply voltage of 2.5 V.

It is to be noted here that, while description is given of electric characteristic changeover between the type A and the type B, naturally the configuration is actually determined such that electric characteristic changeover among a required number of types is carried out in response to the number or variations of memory types with which the semiconductor memory device 1 can cope.

Further, while the signal paths shown in the figures are formed as of an input type, an output type and a bidirectional type, each particular signal path may be considered corresponding to one of the three types. For example, it may be considered that, as a signal path for the command CMD or the data input DQin, the configuration of the input signal shown in the figures is adopted.

Meanwhile, an internal logic 40 shown in FIGS. 29 to 33 is a block which comprehensively shows the selector 23, PLL block 24 and interface module group 21.

First, the example shown in FIG. 29 is described.

The IO buffer 22 includes a type A buffer 44, a type B buffer 48 and switches 41 and 53 as an input system.

The IO buffer 22 further includes a type A buffer 45, a type B buffer 49 and switches 42 and 54 as an output system.

The IO buffer 22 further includes a type A buffer 46, a type A 3-state buffer 47, a type B buffer 50, a type B 3-state buffer 51, and switches 43, 55 and 56 as a bidirectional system.

The mode designation signal Md is supplied to the mode interpretation block 25 through a buffer amplifier 52.

Meanwhile, as power supply lines introduced from the outside of the semiconductor memory device 1, a type A buffer power supply line 70, a type B buffer power supply line 71, an internal logic power supply line 72 and a mode buffer power supply line 73 are formed.

For example, the type A buffer power supply line 70 is used as a power supply line for 3.3 V and supplies the power to the type A buffers 44, 45 and 46, type A 3-state buffer 47 and switches 41, 42 and 43.

Meanwhile, the type B buffer power supply line 71 is used as a power supply line, for example, for 2.5 V and supplies the power to the type B buffers 48, 49 and 50 and type B 3-state buffer 51.

The internal logic power supply line 72 supplies an operation power supply voltage to the circuit components in the internal logic 40 such as the interface module group 21 and the PLL block 24 and the mode interpretation block 25 and supplies an operation power supply voltage for switching operation of the switches 53, 54, 55 and 56.

The mode buffer power supply line 73 supplies an operation power supply voltage to the buffer amplifier 52.

It is to be noted that, while, in the example shown, an operation power supply voltage is supplied to the switches 41, 42 and 43 through the type A buffer power supply line 70, the operation power supply voltage may be any power supply voltage by which the switches 41, 42 and 43 can be switched, and it may be supplied to the switches 41, 42 and 43 from some other power supply line.

The switches 41, 42, 43, 53, 54, 55 and 56 are configured for changeover between an a terminal corresponding to the type A and a b terminal corresponding to the type B.

The switches 41, 42, 43, 53, 54, 55 and 56 change over the connection terminal in response to the mode signal Smd from the mode interpretation block 25.

For example, if the mode signal Smd indicates a memory type corresponding to the type A, then the switches 41, 42, 43, 53, 54, 55 and 56 select the a terminal. Consequently, in the IO buffer 22, the type A buffers 44, 45 and 46 and the type A 3-state buffer 47 function to carry out inputting and outputting of various signals, and inputting and outputting buffer operation in accordance with the memory type corresponding to the type A is implemented.

If the mode signal Smd indicates a memory type corresponding to the type B, then the switches 41, 42, 43, 53, 54, 55 and 56 select the b terminal. Consequently, in the IO buffer 22, the type B buffers 48, 49 and 50 and the type B 3-state buffer 51 function to carry out inputting and outputting of various signals, and inputting and outputting buffer operation in accordance with the memory type corresponding to the type B is implemented.

It is to be noted here that, while the model of changeover between two electric characteristic types of the type A and the type B is described, it is estimated that actually the number of types of buffer electric characteristics among which changeover is to be executed becomes greater depending upon the number or types of interface modules 21 to be incorporated.

For example, as electromagnetic characteristic types which are different in the power supply voltage or the delay characteristic, a great number of types such as a type C, a type D, . . . are required. In this instance, buffer amplifiers of the different types are incorporated similarly to the types A and B, and a configuration for selecting the types using the switches 41, 42, 43, 53, 54, 55 and 56 should be adopted.

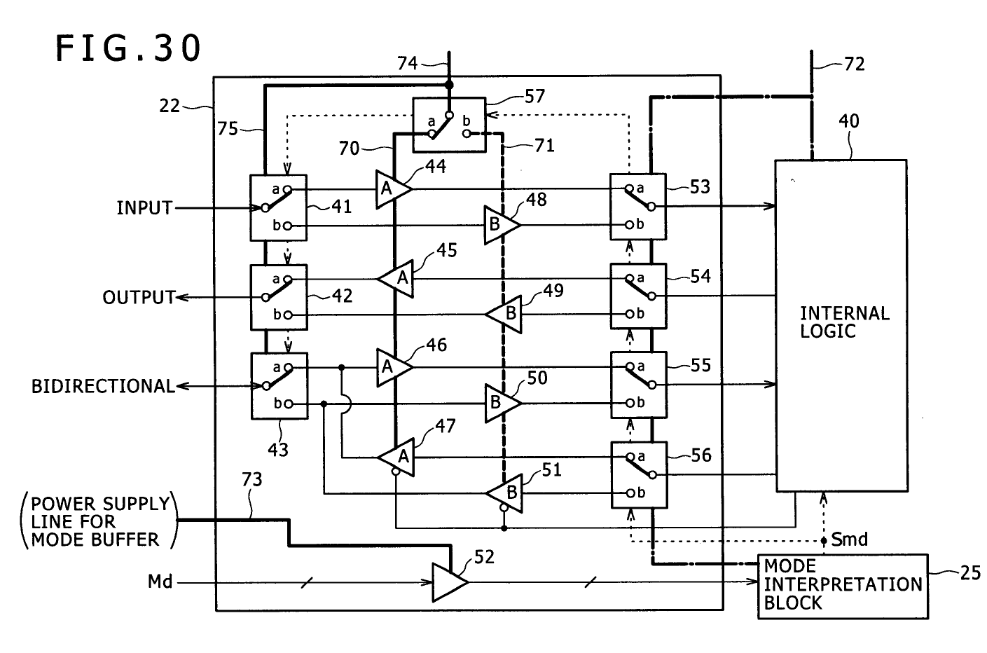

Although different configurations are described below with reference to FIGS. 30 to 33, the configuration should be considered extensively so that it may be ready for a greater number of electric characteristic types similarly.

Now, another example of the configuration of the IO buffer 22 is described with reference to FIG. 30.

In the example of FIG. 30, three power supply lines are introduced to the semiconductor memory device 1 from the outside. In particular, the semiconductor memory device 1 has a buffer power supply line 74, a mode buffer power supply line 73 and an internal logic power supply line 72.

The buffer power supply line 74 is for the switches 41, 42 and 43, and the connection destination of the buffer power supply line 74 is changed over between the A type system and the B type system by a power supply line switch 57.

The mode signal Smd is supplied to the switches 41, 42, 43, 53, 54, 55 and 56 and the power supply line switch 57.

To the buffer power supply line 74, a predetermined power supply voltage is supplied depending upon as a memory of what memory type the semiconductor memory device 1 should be used when the semiconductor memory device 1 is mounted on a circuit board of an electronic apparatus.

For example, where the semiconductor memory device 1 is used as an SDR in the electronic apparatus, the buffer power supply line 74 is connected fixedly to a power supply line of 3.3 V by a circuit board wiring line. On the other hand, where the semiconductor memory device 1 is used as a DDR in the electronic apparatus, the buffer power supply line 74 is connected fixedly to a power supply line of 2.5 V by a circuit board wiring line.

Then, if the mode signal Smd indicates a memory type corresponding to the type A, then the switches 41, 42, 43, 53, 54, 55 and 56 select the a terminal, and also the power supply line switch 57 selects the a terminal.

In this instance, since the buffer power supply line 74 is a 3.3 V power supply line, the power supply voltage of 3.3 V is supplied to the type A buffers 44, 45 and 46 and the type A 3-state buffer 47. Accordingly, in the IO buffer 22, the type A buffers 44, 45 and 46 and the type A 3-state buffer 47 function to carry out inputting and outputting of various signals, and inputting and outputting buffer operation in accordance with a memory type corresponding to the type A is implemented.

On the other hand, if the mode signal Smd indicates a memory type corresponding to the type B, then the switches 41, 42, 43, 53, 54, 55 and 56 select the b terminal, and also the power supply line switch 57 selects the b terminal.

In this instance, since the buffer power supply line 74 is a 2.5 V power supply line, the power supply voltage of 2.5 V is supplied to the type B buffers 48, 49 and 50 and the type B 3-state buffer 51. Accordingly, in the IO buffer 22, the type B buffers 48, 49 and 50 and the type B 3-state buffer 51 function to carry out inputting and outputting of various signals, and inputting and outputting buffer operation in accordance with a memory type corresponding to the type B is implemented.

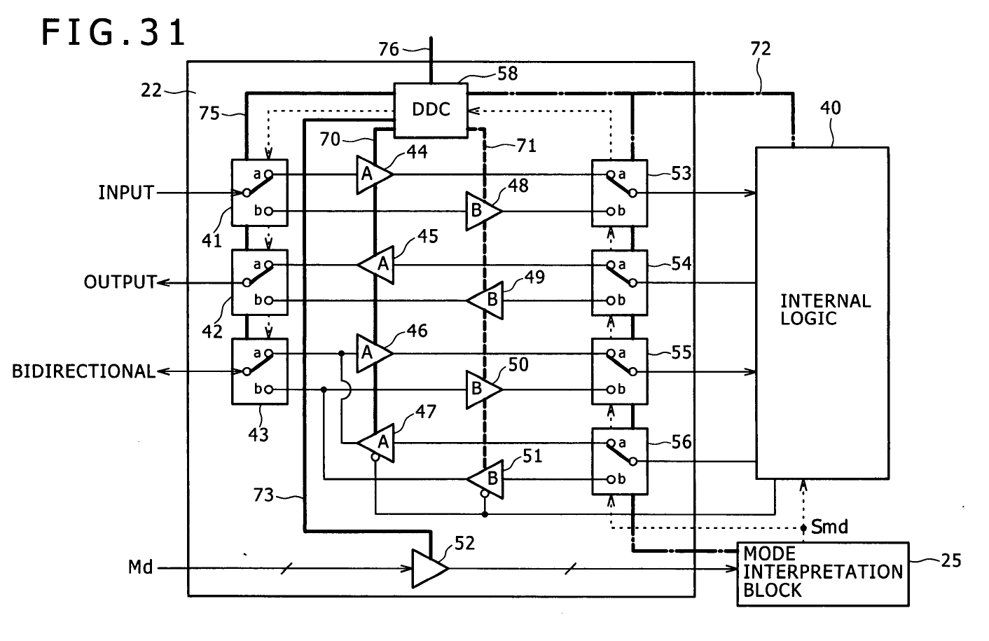

Now, an example shown in FIG. 31 is described.

Referring to FIG. 31, in the example shown, only one power supply line, that is, a common power supply line 76, is introduced to the semiconductor memory device 1 from the outside. Further, a DC/DC converter (DDC) 58 is provided in the IO buffer 22.

The DC/DC converter 58 carries out voltage conversion of the power supply voltage from the common power supply line 76 and supplies predetermined voltages to individual power supply lines.

In particular, the DC/DC converter 58 supplies a power supply voltage to the switches 41, 42 and 43 through a switch power supply line 75.

Meanwhile, the DC/DC converter 58 supplies the power supply voltage of 3.3 V to the type A buffers 44, 45 and 46 and the type A 3-state buffer 47 through the type A buffer power supply line 70.

Further, the DC/DC converter 58 supplies the power supply voltage of 2.5 V to the type B buffers 48, 49 and 50 and the type B 3-state buffer 51 through the type B buffer power supply line 71.

Furthermore, the DC/DC converter 58 supplies a power supply voltage to the buffer amplifier 52 through the mode buffer power supply line 73.

Further, the DC/DC converter 58 supplies a power supply voltage to the internal logic 40, switches 53, 54, 55 and 56 and mode interpretation block 25 through the internal logic power supply line 72.

The mode signal Smd from the mode interpretation block 25 is supplied to the switches 41, 42, 43, 53, 54, 55 and 56 and the DC/DC converter 58. The DC/DC converter 58 selectively carries out outputting of a power supply voltage to the type A buffer power supply line 70 and outputting of another power supply voltage to the type B buffer power supply line 71 in response to the mode signal Smd.

Then, if the mode signal Smd indicates a memory type corresponding to the type A, then the switches 41, 42, 43, 53, 54, 55 and 56 select the a terminal, and the DC/DC converter 58 carries out supply of operation power supply voltages to the switch power supply line 75, mode buffer power supply line 73 and internal logic power supply line 72 and supply of the power supply voltage of 3.3 V to the type A buffer power supply line 70.

Accordingly, in the IO buffer 22, the type A buffers 44, 45 and 46 and the type A 3-state buffer 47 function to carry out inputting and outputting of various signals, and inputting and outputting buffer operation in accordance with a memory type corresponding to the type A is implemented.

On the other hand, if the mode signal Smd indicates a memory type corresponding to the type B, then the switches 41, 42, 43, 53, 54, 55 and 56 select the b terminal, and the DC/DC converter 58 supplies individual operation power supply voltages to the switch power supply line 75, mode buffer power supply line 73 and internal logic power supply line 72 and supplies the power supply voltage of 2.5 V to the type B buffer power supply line 71.

Accordingly, in the IO buffer 22, the type B buffers 48, 49 and 50 and the type B 3-state buffer 51 function to carry out inputting and outputting of various signals, and inputting and outputting buffer operation in accordance with the memory type corresponding to the type B is implemented.

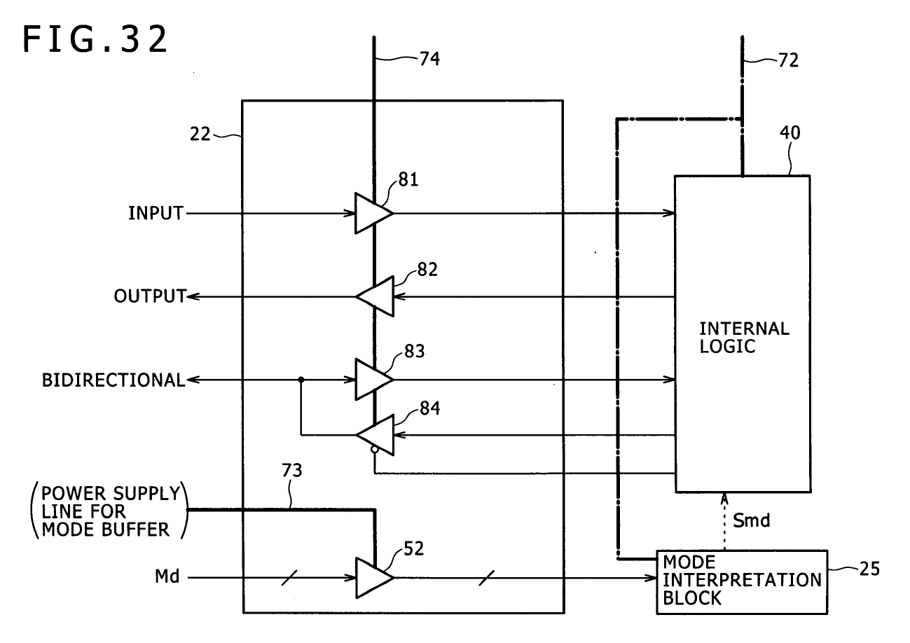

Now, an example shown in FIG. 32 is described. It is to be noted that, in the configuration example shown in FIG. 32, the IO buffer 22 does not carry out internal changeover in accordance with the mode signal Smd.

In this instance, the IO buffer 22 includes a common buffer 81 as an input system. Further, the IO buffer 22 includes a common buffer 82 as an output system. Further, the IO buffer 22 includes a common buffer 83 and a common 3-state buffer 84 as a bidirectional system.

The common buffers 81, 82 and 83 and the common 3-state buffer 84 are buffer amplifiers which can permit the voltage range and the delay with an application voltage.

Further, three power supply lines including a buffer power supply line 74, a mode buffer power supply line 73 and an internal logic power supply line 72 are introduced to the semiconductor memory device 1 from the outside.

The buffer power supply line 74 is formed for supplying power to the common buffers 81, 82 and 83 and the common 3-state buffer 84.

The internal logic power supply line 72 is formed for supplying power to the internal components of the internal logic 40 and the mode interpretation block 25.

The mode buffer power supply line 73 is formed for supplying power to the buffer amplifier 52.

To the buffer power supply line 74, a predetermined power supply voltage is supplied depending upon as a memory of what memory type the semiconductor memory device 1 should be used when the semiconductor memory device 1 is mounted on a circuit board of an electronic apparatus.

For example, where the semiconductor memory device 1 is used as an SDR in the electronic apparatus, the buffer power supply line 74 is connected fixedly to the power supply line of 3.3 V by a circuit board wiring line.

On the other hand, where the semiconductor memory device 1 is used as a DDR in the electronic apparatus, the buffer power supply line 74 is connected fixedly to the power supply line of 2.5 V by a circuit board wiring line.

In the present configuration, the IO buffer 22 need not carry out changeover operation based on the mode signal Smd from the mode interpretation block 25. Changeover operation in accordance with the mode signal Smd is carried out by the selector 23 and the PLL block 24 in the internal logic 40.

For example, where the semiconductor memory device 1 is used as an SDR, the buffer power supply line 74 is used as a power supply line for 3.3 V, and the common buffers 81, 82 and 83 and the common 3-state buffer 84 operate with the power supply voltage of 3.3 V.

On the other hand, where the semiconductor memory device 1 is used as a DDR, the buffer power supply line 74 is used as a power supply line for 2.5 V, and the common buffers 81, 82 and 83 and the common 3-state buffer 84 operate with the power supply voltage of 2.5 V.

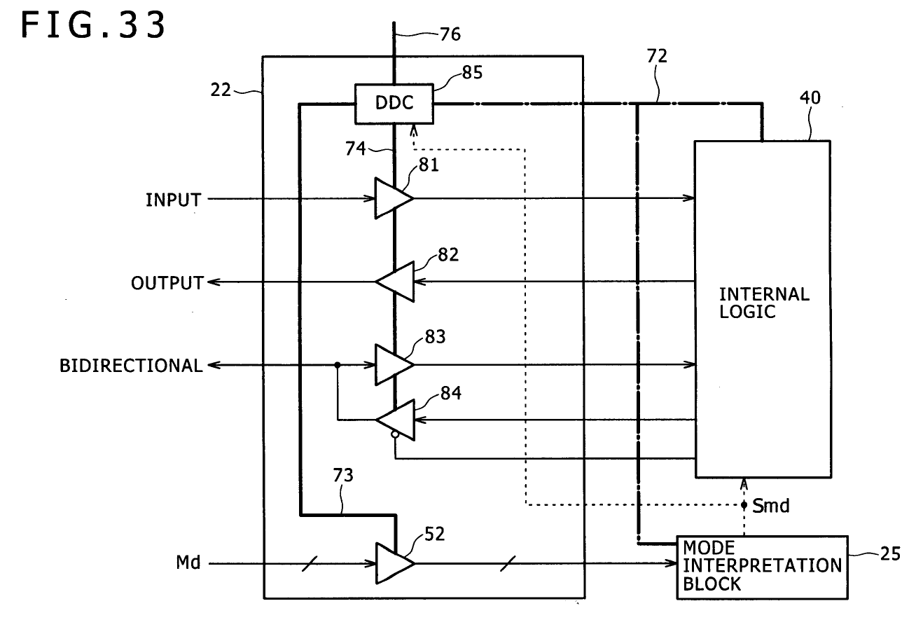

Now, the example of FIG. 33 is described.

While the example of FIG. 33 includes common buffers 81, 82 and 83 and a common 3-state buffer 84 similarly to the example of FIG. 32, only one power supply line, that is, only a common power supply line 76, is introduced to the semiconductor memory device 1 from the outside. A DC/DC converter 85 is provided in the IO buffer 22.

The DC/DC converter 85 carries out voltage conversion of a power supply voltage from the common power supply line 76 and supplies power of predetermined voltages to the individual power supply lines.

In particular, the DC/DC converter 85 supplies a power supply voltage to the common buffers 81, 82 and 83 and the common 3-state buffer 84 through the buffer power supply line 74.

Meanwhile, the DC/DC converter 85 supplies another power supply voltage to the buffer amplifier 52 through the mode buffer power supply line 73.

Further, the DC/DC converter 85 supplies a further power supply voltage to the internal logic 40 and the mode interpretation block 25 through the internal logic power supply line 72.

The mode signal Smd from the mode interpretation block 25 is supplied to the DC/DC converter 85 in the IO buffer 22. The DC/DC converter 85 changes over the power supply voltage to be supplied to the buffer power supply line 74 in accordance with the mode signal Smd.

For example, if the mode signal Smd indicates the SDR mode, then the DC/DC converter 85 supplies the individual power supply voltages to the mode buffer power supply line 73 and the internal logic power supply line 72 and supplies the power supply voltage of 3.3 V to the buffer power supply line 74.

Consequently, the common buffers 81, 82 and 83 and the common 3-state buffer 84 carry out inputting and outputting buffer operation suitable for the SDR.

On the other hand, if the mode signal Smd indicates the DDR mode, then the DC/DC converter 85 supplies the individual power supply voltages to the mode buffer power supply line 73 and the internal logic power supply line 72 and supplies the power supply voltage of 2.5 V to the buffer power supply line 74.

Consequently, the common buffers 81, 82 and 83 and the common 3-state buffer 84 carry out inputting and outputting buffer operation suitable for the DDR.

Where the IO buffer 22 has such configurations as described hereinabove with reference to FIGS. 29 to 33, inputting and outputting buffer operation suitable for the individual modes or memory types can be executed.

### 6. Other Examples of the Configuration of the Semiconductor Memory Device

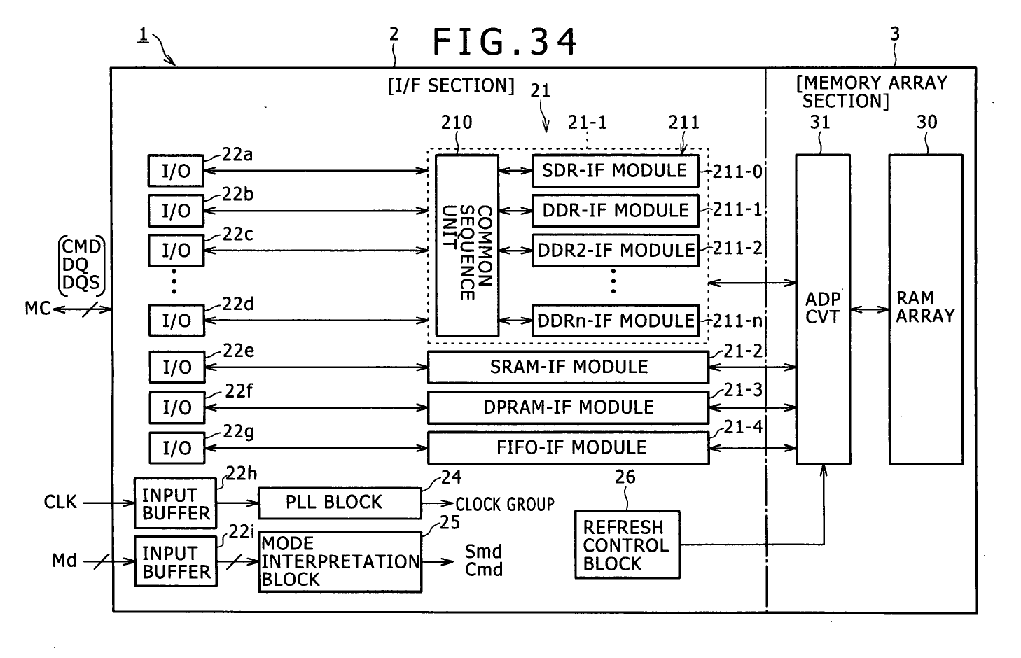

While the configuration of the semiconductor memory device 1 is described hereinabove with reference to FIG. 2, the semiconductor memory device 1 may have some other configurations. Another example of the configuration is shown in FIG. 34.

Referring to FIG. 34, the configuration example shown includes a special-purpose IO buffer for each of the interface modules 211-0 to 211-n, 21-2, 21-3 and 21-4.

In particular, the semiconductor memory device 1 includes an IO buffer 22a for the SDR-IF module 211-0, an IO buffer 22b for the DDR-IF module 211-1, an IO buffer 22c for the DDR2-IF module 211-2, an IO buffer 22d for the DDR(n)-IF module 211-n, an IO buffer 22e for the SRAM-IF module 21-2, an IO buffer 22f for the DPRAM-IF module 21-3 and an IO buffer 22g for the FIFO-IF module 21-4.

The semiconductor memory device 1 further includes an input buffer 22h corresponding to the system clock CLK such that the system clock CLK is supplied to the PLL block 24 through the input buffer 22h.

The semiconductor memory device 1 further includes an input buffer 22i corresponding to the mode designation signal Md such that the mode designation signal Md is supplied to the mode interpretation block 25 through the input buffer 22i.

In this instance, the IO buffers 22a to 22g individually have special-purpose input and output signal systems and buffer amplifiers and connection terminals for the interface modules 211-0 to 211-n, 21-2, 21-3 and 21-4 corresponding thereto.

For example, the IO buffer 22a corresponding to the SDR-IF module 211-0 has an input terminal and an input buffer for the command CMD, an input terminal and an input buffer for the data input DQin, and an output terminal and an output buffer for the data output DQout. Naturally, the buffers in the IO buffer 22a have an electric characteristic suitable for the SDR.

On the other hand, for example, the IO buffer 22b corresponding to the DDR-IF module 211-1 has an input terminal and an input buffer for the command CMD, an input terminal and an input buffer for the data input DQin, an output terminal and an output buffer for the data output DQout, and an input/output terminal and an input/output buffer for the data strobe signal DQS. Naturally, the buffers in the IO buffer 22b have an electric characteristic suitable for the DDR.

Where the semiconductor memory device 1 has such a configuration as described above, when it is mounted on a circuit board of an electronic apparatus, an IO buffer to be connected to the memory controller 100 is selected from among the IO buffers 22a to 22g depending upon as a memory of what memory type the semiconductor memory device 1 should be used.

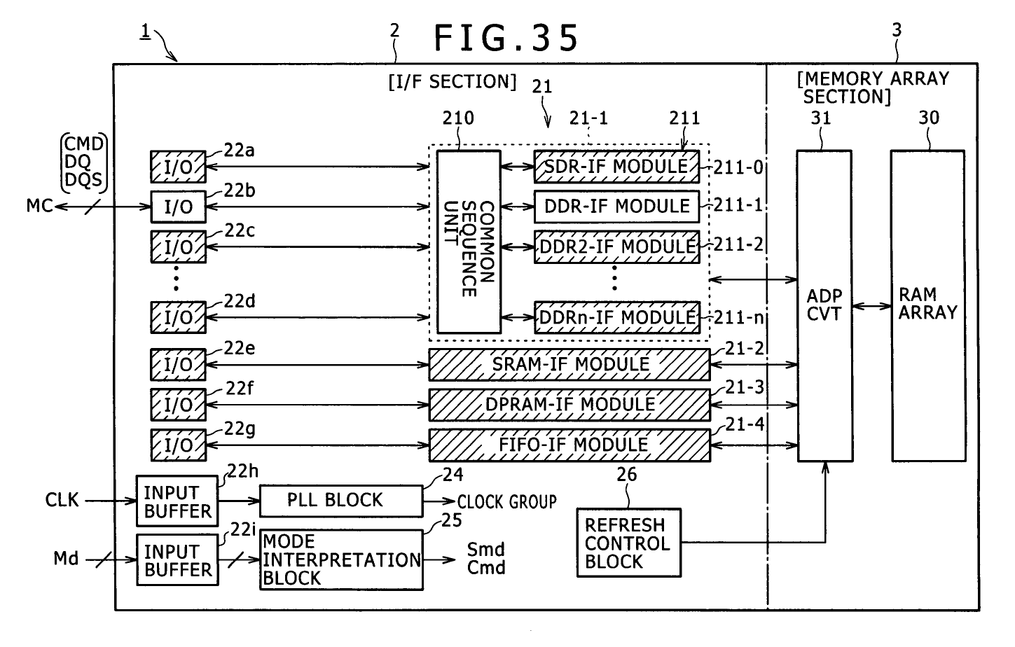

For example, where the semiconductor memory device 1 is to be used as the DDR in the electronic apparatus, for example, a board wiring line scheme is designed such that a terminal of the IO buffer 22b is connected to the memory controller 100. Consequently, in this instance, a state wherein inputting and outputting of various signals between the memory controller 100 and the DDR-IF module 211-1 through the IO buffer 22b as shown in FIG. 35 are carried out is established. At this time, the other IO buffers 22a and 22c to 22g are not used.

Naturally, the mode designation signal Md is set to a signal indicative of the DDR mode, and the mode interpretation block 25 provides a mode signal Smd representative of the DDR mode to the PLL block 24. Consequently, the PLL block 24 supplies a processing clock group to the DDR-IF module 211-1 so that the DDR-IF module 211-1 functions while it stops clock supply to the other interface modules 211-0, 211-2 to 211-n and 21-2 to 21-4 so that they are placed into an operation off state.

Consequently, the semiconductor memory device 1 functions as a DDR.

In the configuration described above, the necessity for the selector 23 shown in FIG. 2 is eliminated.

It is to be noted that, depending upon the power supply configuration for the IO buffers 22a to 22g, the mode signal Smd is used to supply the buffer operation power, for example, of 2.5 V to the IO buffer 22b. Or, where a common power supply line to the IO buffers 22a to 22g is formed, the power supply line may be connected to the power supply line of the 2.5 V type by substrate design.

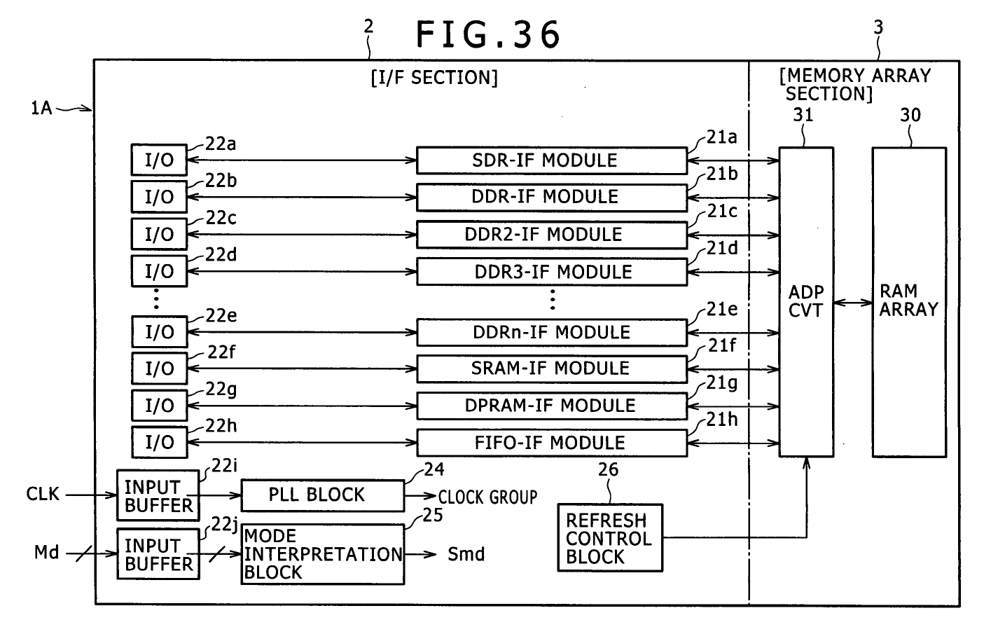

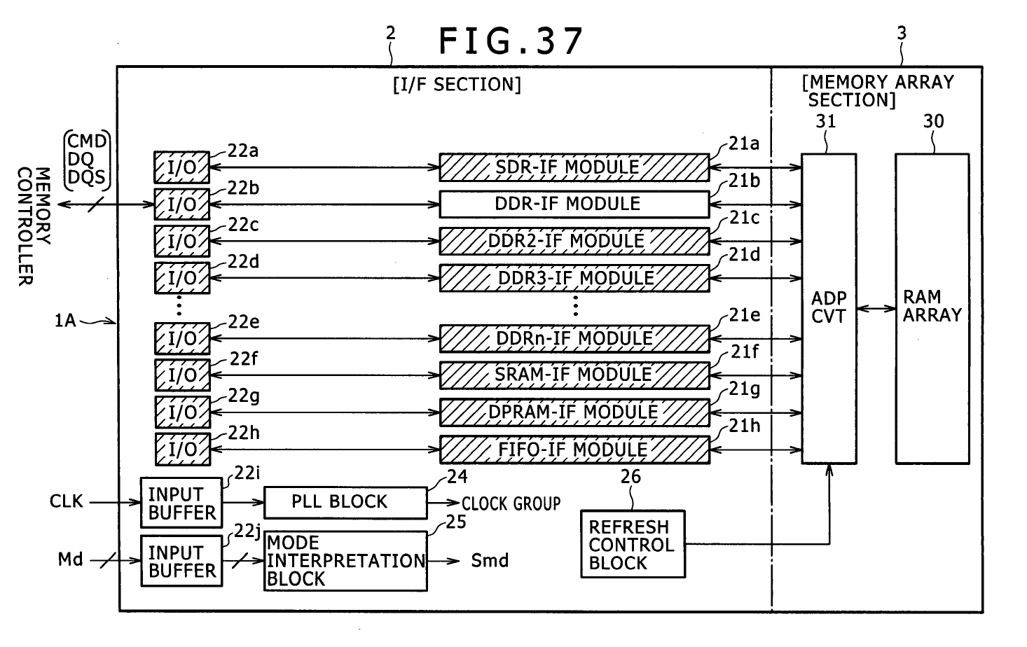

It is to be noted that, while FIGS. 34 and 35 show a different example of the configuration corresponding to the configuration of FIG. 2, such a configuration as shown in FIGS. 36 and 37 may be formed as another similar configuration example corresponding to the configuration of FIG. 6. The configuration shown in FIGS. 36 and 37 has a basic concept similar to that of FIGS. 34 and 35, and therefore, detailed description thereof is omitted herein to avoid redundancy.

While the embodiment of the present invention is described above, where the semiconductor memory device 1 of the embodiment described above is used, it can implement simplification of the circuit scale and suppress increase of the power consumption and can be used as memories of various memory types. Besides, the necessity for a refresh command from the outside is eliminated, and it is possible to carry out refreshment in response to an access situation. Consequently, efficient refresh control can be carried out and efficient memory accessing can be carried out, and besides, improvement in efficiency in apparatus fabrication and design and stabilization in fabrication can be implemented.

For example, if supply of a memory of a certain memory type for use in an electronic apparatus which incorporates a memory of the memory type becomes unstable, then if the memory is replaced by the semiconductor memory device 1 and the semiconductor memory device 1 is set so that it executes operation similar to that of the memory formerly used, then fabrication of the apparatus can be continued without changing the design of a memory control circuit or peripheral circuits.

Further, where a new electronic apparatus is to be designed, if the semiconductor memory device 1 is adopted as a memory chip to be incorporated in the electric apparatus, then the electronic apparatus can be designed efficiently with a high degree of freedom. Also in a case wherein it is intended to carry out a specification change of the memory itself, that is, a change of the memory type, in the future, the semiconductor memory device 1 can cope with the case readily.

It is to be noted that the semiconductor memory device of the present invention is not limited to that of the configuration of the embodiment described hereinabove and may be modified in various forms.

The number of interface modules to be incorporated is at least two such that the semiconductor memory device can function as memories of at least two different memory types.

It should be understood by those skilled in the art that various modifications, combinations, sub-combinations and alternations may occur depending on design requirements and other factors insofar as they are within the scope of the appended claims or the equivalent thereof.

What is claimed is:

1. A semiconductor memory device, comprising:
a memory array section wherein a memory array which requires a refresh operation is formed;
an interface section configured to carry out an interfacing process between an external apparatus and said memory array section; and
a refresh control block for controlling the refresh operation;
said interface section configured to include a plurality of interface modules individually corresponding to a plurality of memory types and selectively applied to the interfacing process between the external apparatus and said memory array section;
said refresh control block having a function of issuing a refresh command within a refresh cycle and another function of preventing, if, upon issuance of the refresh command, an access command and the refresh command to said memory array are estimated to collide with each other, the collision.

2. The semiconductor memory device according to claim 1, wherein said refresh control block further has a function of skipping the refresh command to an address of said memory array which has been accessed within the refresh cycle thereby eliminating the necessity for the refreshment.

3. The semiconductor memory device according to claim 2, wherein said refresh control block monitors accessed addresses and skips the refresh command when said refresh control block tries to doubly access any of the accessed addresses within the refresh cycle.

4. The semiconductor memory device according to claim 3, wherein said refresh control block includes a memory configured to store address information, and stores information of any address accessed within the refresh cycle into said memory, reads out the information stored in said memory at a timing of accessing to a refresh address and skips the refresh command if the read out information represents an address accessed once within the refresh cycle.

5. The semiconductor memory device according to claim 2, wherein
said memory array includes a plurality of banks which can be accessed independently of each other, and
said refresh control block does not interrupt the refresh operation if that one of said banks which is currently being accessed and that one of said banks which should be refreshed are different from each other.

6. The semiconductor memory device according to claim 2, wherein
said memory array includes a plurality of banks which can be accessed independently of each other, and
said refresh control block interrupts the refresh operation if that one of said banks which is currently being accessed and that one of said banks which should be refreshed are same as each other.

7. The semiconductor memory device according to claim 2, wherein
said memory array includes a plurality of banks which can be accessed independently of each other, and
if said refresh control block executes an access process to one of said banks before the bank is refreshed, then said refresh control block skips the accessed address.

8. The semiconductor memory device according to claim 2, wherein
said memory array includes a plurality of banks which can be accessed independently of each other, and
said refresh control block does not interrupt the refresh operation if that one of said banks which is currently being accessed and that one of said banks which should be refreshed are different from each other, but said refresh control block interrupts the refresh operation if that one of said banks which is currently being accessed and that one of said banks which should be refreshed are same as each other whereas, if said refresh control block executes an access process to one of said banks before the bank is refreshed, then said refresh control block skips the accessed address.

9. An operation method for a semiconductor memory device having an interface function in accordance with a memory type between a memory array section wherein a memory array which requires a refresh operation is formed and an external apparatus, comprising the steps of:
issuing a refresh command within a refresh cycle; and
skipping, if an access command and the refresh command to the memory array collide with each other, the refresh command for any address of the memory array accessed within the refresh cycle to eliminate the necessity for the refreshment for the address.
